(19) United States
(12) Patent Application Publication
(10) Pub. No.: US 2007/0066014 A1
(43) Pub. Date: Mar. 22, 2007

(54) Nonvolatile memory device and method of fabricating the same

(75) Inventors: Ki-Tae Park, Hwaseong-si (KR); Jung-Dal Choi, Suwon-si (KR)

Correspondence Address: F. Chau & Associates, LLC, 130 Woodbury Road, Woodbury, NY, 11797, US

(73) Assignee: Samsung Electronics Co., Ltd., Suwon-si (KR)

(21) Appl. No.: 11/516,541

(22) Filed: Sep. 6, 2006

(30) Foreign Application Priority Data
Sep. 22, 2005 (KR) 2005-88227

(51) Int. Cl. H01L 21/336

(52) U.S. Cl. 438/257; 438/264; 438/258

(57) ABSTRACT

A nonvolatile memory device includes a device isolation layer defining an active region protruding from a semiconductor substrate and an active region separation layer isolating the active region into first and second active regions spaced apart from each other. The active region separation layer is narrower than the device isolation layer. Moreover, the nonvolatile memory device further includes first and second memory cells formed in the first and second active regions, respectively.

### CROSS-REFERENCE TO RELATED APPLICATION

This application claims priority from Korean Patent Application No. 10-2005-0088227, filed Sep. 22, 2005, the disclosure of which is hereby incorporated by reference herein in its entirety.

### BACKGROUND OF THE INVENTION

1. Technical Field

The present disclosure relates to a nonvolatile memory device, and more particularly, to a nonvolatile memory device capable of storing data of two or more bits and a method of fabricating the same.

2. Description of the Related Art

EPROMs (erasable programmable read-only memories), EEPROMs (electrically erasable programmable read-only memories), and flash EEPROMs are nonvolatile memories that can retain data without power. The above-mentioned nonvolatile memories are widely used in various technical fields.

Moreover, nonvolatile memories using an insulating material capable of locally trapping a charge have been developed. In comparison to nonvolatile semiconductor memories using a floating gate, nonvolatile memories using an insulating material can be fabricated by a more simplified process and can also be used to implement highly-integrated memory chips. A typical example of the insulating material capable of trapping a charge is silicon nitride. Typically, oxide-nitride-oxide (ONO) layer, which is configured to include silicon oxide layers and a silicon nitride layer sandwiched therebetween, may be used as a charge storage layer of a nonvolatile memory.

FIG. 1A is a sectional view of a conventional nonvolatile memory device using an ONO layer, which is described in U.S. Pat. No. 5,168,334 issued to Mitchell et al. FIG. 1B is an equivalent circuit diagram of the nonvolatile memory device in FIG. 1A.

Referring to FIGS. 1A and 1B, a nonvolatile memory device 10 includes a substrate 11, source/drain regions 17 on the substrate, an ONO layer 13 on a channel between the source/drain regions 17, and a polysilicon layer 15 on the ONO layer 13. The ONO layer 13 includes a silicon oxide layer 13a, a silicon nitride layer 13b, and a silicon oxide layer 13c that are sequentially stacked on the channel. As illustrated in FIG. 1B, the nonvolatile memory device 10 can be understood as one transistor 16. Depending on whether the silicon nitride layer 13b traps a charge, the nonvolatile memory device 10 stores a single-bit data indicating one of logic levels ‘0’ and ‘1’.

There is a demand for a nonvolatile memory device that can represent two or more logic levels without an increase in its size, thereby providing increased data storage capacity. To this end, a variety of two-bit nonvolatile memory devices have been introduced.

FIG. 2A is a sectional view of a conventional nonvolatile memory device, which is described in U.S. Pat. No. 5,768,192 issued to Boaz Eitan. FIG. 2B is an equivalent circuit diagram of the nonvolatile memory device in FIG. 2A.

Referring to FIGS. 2A and 2B, a nonvolatile memory device 20 includes a substrate 21, source/drain regions 27 on the substrate, an ONO layer 23 on a channel between the source/drain regions 27, and a polysilicon layer 25 on the ONO layer 23. The ONO layer 23 includes a silicon oxide layer 23a, a silicon nitride layer 23b, and a silicon oxide layer 23c that are sequentially stacked on the channel. The silicon nitride layer 23b includes two charge storage regions 23L and 23R. The charge storage regions 23L and 23R store a carrier (or a charge) selectively and independently. When proper voltages are applied to the gate 25, the source/drain regions 27 and the substrate 21, a charge is selectively and independently injected into the charge storage regions 23L and 23R near to the source/drain regions 27.

In FIG. 2A, the charge storage regions 23L and 23R are represented in shade. As illustrated in FIG. 2B, the nonvolatile memory device 20 can be understood as three transistors 26L, 26C and 26R whose channels L_{S1}, L_{C} and L_{S2} are connected in parallel. Threshold voltages of the transistors 26L and 26R vary depending on the amounts of charge injected into the charge storage regions 23L and 23R. The transistors 26L and 26R are regarded as short-channel transistors with a channel width of about 50 nm or less.

The nonvolatile memory device 20 is quite simple in structure and its fabrication costs are relatively inexpensive. However, the nonvolatile memory device 20 may be restricted with regard to operating voltage because three transistors 26L, 26C and 26R are simultaneously controlled by one gate 25. Consequently, a signal difference between logic levels ‘0’ and ‘1’ may decrease to thereby reduce a sensing margin. In addition, with the trend of high integration of semiconductor devices, the distance between the source/drain regions 27 may decrease to reduce the distance between the charge storage regions 23L and 23R. Considering the fact that charges stored in the silicon nitride layer 23b can migrate by lateral diffusion, the effective distance between the charge storage regions 23L and 23R may decrease. As a result, the charge storage regions 23L and 23R may be physically connected to each other, which may make it difficult to discriminate between two different bit data values. This may obstruct the scale-down of the nonvolatile memory device 20, which is necessary to implement an inexpensive, high-density nonvolatile memory device.

FIG. 3A is a sectional view of a conventional two-bit nonvolatile memory device, which is described in U.S. Pat. No. 6,706,599 issued to Sadd et al. FIG. 3B is an equivalent circuit diagram of the nonvolatile memory device in FIG. 3A.

Referring to FIGS. 3A and 3B, a nonvolatile memory device 30 includes a substrate 31, source/drain regions 37 on the substrate, an ONO layer 33 on a channel between the source/drain regions 37, and a polysilicon layer 35 on the ONO layer 33. The ONO layer 33 includes a silicon oxide layer 33a, a silicon nitride layer 33b, and a silicon oxide layer 33c that are sequentially stacked on the channel. The silicon nitride layer 33b includes two charge storage regions 33L and 33R. The two charge storage regions 33L and 33R are physically separated by a silicon oxide layer 32a. In the memory device 30, the two charge storage regions 33L and 33R are not electrically connected by charge diffusion even when the distance between source/drain regions 37 decreases with the trend of high integration of semiconductor devices. The nonvolatile memory device 30 can be more highly integrated for having the operational characteristics of the memory device 20 in FIG. 2A. However, like the nonvolatile memory device 20, the nonvolatile memory device 30 may be restricted with regard to operating voltage because three transistors 36L, 36C and 36R should be simultaneously controlled by one gate 35. Consequently, a signal difference between logic levels ‘0’ and ‘1’ may decrease to thereby reduce a sensing margin.

FIG. 4A is a sectional view of a conventional nonvolatile memory device, which is described in U.S. Pat. No. 6,248,633 issued to Ogura et al. FIG. 4B is an equivalent circuit diagram of the nonvolatile memory device in FIG. 4A.

Referring to FIGS. 4A and 4B, a nonvolatile memory device 30 includes a substrate 41, source/drain regions 47 on the substrate, a select gate 45C and control gates 45L/45R on a channel between the source/drain regions 47, a ONO layer 43 between control gates 45L/45R and the substrate 41. The ONO layer 43 includes a silicon oxide layer 43a, a silicon nitride layer 43b, and a silicon oxide layer 43c. The control gates 45L and 45R are independently controllable, and respectively disposed on both sidewalls of the select gate 45C. The ONO layer 43 includes charge storage regions 43L and 43R under the control gates 45L and 45R, respectively. The select gate 45C is insulated from a substrate 41 by a silicon oxide layer 42g, and is insulated from the control gates 45L and 45R by a silicon oxide layer 42s.

As the nonvolatile memory device 40 can be fabricated using a process of forming sidewall spacers of a gate, the nonvolatile memory device 40 can be reduced in size by forming the control gates 45L and 45R of nanoscale size. Also, as the independent control gates 45L and 45R are formed respectively in the charge storage regions 43L and 43R and the select gate 45C can controlled independently, an optimized voltage can be applied to each gate. Consequently, a signal difference between logic levels ‘0’ and ‘1’, which are bit data values of the nonvolatile memory device 40, may increase to enhance a sensing margin. However, a peripheral circuit of the nonvolatile memory device 40 is complicated because the nonvolatile memory device 40 has many gates to be controlled. Moreover, the select gate 45C discussed above may also make it more difficult to obtain a highly integrated nonvolatile memory device.

Thus, there is a need for nonvolatile memory devices that are inexpensive to manufacture and which provide high density, as well as high reliability.

### SUMMARY OF THE INVENTION

In accordance with an exemplary embodiment of the present invention a nonvolatile memory device is provided. The nonvolatile memory device includes: a device isolation layer defining an active region protruding from a semiconductor substrate and an active region separation layer isolating the active region into first and second active regions spaced apart from each other. The active region separation layer is narrower than the device isolation layer. Moreover, the nonvolatile memory device further includes first and second memory cells formed respectively in the first and second active regions.

In some exemplary embodiments, the active region isolation layer is shallower than the device isolation layer. Also, the active region isolation layer has a width that is smaller than or equal to the minimum linewidth, and the first and second active regions have a width that is smaller than or equal to the minimum linewidth.

In other exemplary embodiments, the first and second memory cells are formed respectively at a first side of the first active region and a second side of the second active layer, and the first and second sides are outer sides of the active region.

In further exemplary embodiments, the nonvolatile memory devices may further include: a gate line intersecting the first and second active regions and a memory layer interposed between a gate line and the first and second active regions. The first and second memory cells include the memory layer on the first and second sides, respectively, and share the gate line with each other.

In still further exemplary embodiments, the nonvolatile memory devices may further include insulating patterns formed at top portions of the first and second active regions.

In even further exemplary embodiments, the memory layer may include a tunnel oxide layer, a charge storage layer, and an isolation insulating layer that are sequentially stacked. The charge storage layer includes one selected from the group of a silicon nitride layer, a hafnium oxide layer, a lanthanum oxide layer, an aluminum oxide layer, a nanocrystal layer, and a combination thereof.

In yet further exemplary embodiments, the first memory cell may further include first and second impurity regions that are spaced apart from each other on the first side to define a first channel region therebetween, and the second memory cell may further include third and fourth impurity regions that are spaced apart from each other on the second side to define a second channel region therebetween.

In still yet further exemplary embodiments, the gate line may include a pair of gate electrodes spaced apart from each other. The first memory cell may include a first pair of sub-memory cells that share the first and second impurity regions and are controlled respectively by the pair of gate electrodes. The second memory cell may include a second pair of sub-memory cells that share the third and fourth impurity regions and are controlled respectively by the pair of gate electrodes.

In accordance with an exemplary embodiment of the present invention, a method of fabricating a nonvolatile memory device includes: forming a trench for a device isolation layer defining an active region on a semiconductor substrate and a groove separating the active region into a first active region and a second active region. The groove is narrower than the trench. The method further includes forming a first memory cell and a second memory cell in the first active region and the second active region, respectively.

In some exemplary embodiments, the groove may be formed shallower than the trench.

In other exemplary embodiments, the forming of the trench and the groove includes: forming a pair of mask patterns in a predetermined region on the semiconductor substrate, with the pair of mask patterns being spaced apart from each other by a predetermined distance smaller than the minimum linewidth and etching the semiconductor substrate using the pair of mask patterns.

In further exemplary embodiments, the forming of the pair of mask patterns includes: stacking an insulating layer on the semiconductor substrate, depositing a dummy pattern layer on the insulating layer and performing a photolithography process on the dummy pattern layer to form a first dummy pattern and a second dummy pattern, forming a pair of spacers facing each other on sidewalls of the first and second dummy patterns, removing the first and second dummy patterns and etching the insulating layer using the pair of spacers as an etch mask to form insulating layer patterns.

In still further exemplary embodiments, the first and second dummy patterns have the minimum linewidth (F), a distance (X) between the dummy patterns neighboring each other is larger than or equal to F and smaller than or equal to 2F (F≦X≦2F), the pair of mask patterns have a width L smaller than the half of X (L<(X/2)), and the minimum distance (D) between the mask patterns neighboring each other is smaller than F.

In even further exemplary embodiments, the insulating layer may be a stack of a silicon oxide layer and a silicon nitride layer.

In yet further exemplary embodiment, the methods may further include forming a device isolation layer and an active region isolation layer that respectively fill the trench and the groove. The device isolation layer exposes first and second sides that are adjacent respectively to outer sides of top portions of the first and second active regions, and the first and second memory cells are formed respectively on the first and second sides.

In still even further exemplary embodiments, the forming of the first and second memory cells includes: forming a memory layer on the entire top surface of the semiconductor substrate and forming a gate line intersecting the first and second active regions on the memory layer.

In still yet farther exemplary embodiments, the forming of the first and second memory cells includes: forming impurity regions at both sides of the gate line using an ion implantation process, to form first and second impurity regions on the first side, a first channel region between the first and second impurity regions, third and fourth impurity regions on the second side, and a second channel region between the third and fourth impurity regions.

In even yet further exemplary embodiments, the gate line may be formed of a pair of gate electrodes spaced apart from each other.

### BRIEF DESCRIPTION OF THE DRAWINGS

Exemplary embodiments of the present invention can be understood in more detail from the following detailed description taken in conjunction with the accompanying drawings in which:

FIG. 1A is a sectional view of a conventional nonvolatile memory device;

FIG. 1B is an equivalent circuit diagram of the conventional nonvolatile memory device in FIG. 1A;

FIG. 2A is a sectional view of another conventional nonvolatile memory device;

FIG. 2B is an equivalent circuit diagram of the conventional nonvolatile memory device in FIG. 2A;

FIG. 3A is a sectional view of a further another conventional nonvolatile memory device;

FIG. 3B is an equivalent circuit diagram of the conventional nonvolatile memory device in FIG. 3A;

FIG. 4A is a sectional view of a still another conventional nonvolatile memory device;

FIG. 4B is an equivalent circuit diagram of the conventional nonvolatile memory device in FIG. 4A;

FIG. 5A is a perspective view of a nonvolatile memory device according to a first exemplary embodiment of the present invention;

FIGS. 5B through 5D are sectional views taken along lines I-I, II-II and III-III of FIG. 5A;

FIG. 5E is an equivalent circuit diagram of the nonvolatile memory device in FIG. 5A;

FIG. 6A is a perspective view of a nonvolatile memory device according to a second exemplary embodiment of the present invention;

FIGS. 6B through 6D are sectional views taken along lines I′-I′, II′-II′ and III′-III′ of FIG. 6A;

FIG. 7A is a perspective view of a nonvolatile memory device according to a third exemplary embodiment of the present invention;

FIGS. 7B through 7D are sectional views taken along lines I″-I″, II″-II″ and III″-III″ of FIG. 7A;

FIG. 7E is an equivalent circuit diagram of the nonvolatile memory device in FIG. 7A;

FIGS. 8 through 18 are sectional views illustrating a method of fabricating a nonvolatile memory device according to a first exemplary embodiment of the present invention;

FIGS. 19 through 21 are sectional views illustrating a method of fabricating a nonvolatile memory device according to a second exemplary embodiment of the present invention; and

FIGS. 22 through 26 are sectional views illustrating a method of fabricating a nonvolatile memory device according to a third exemplary embodiment of the present invention.

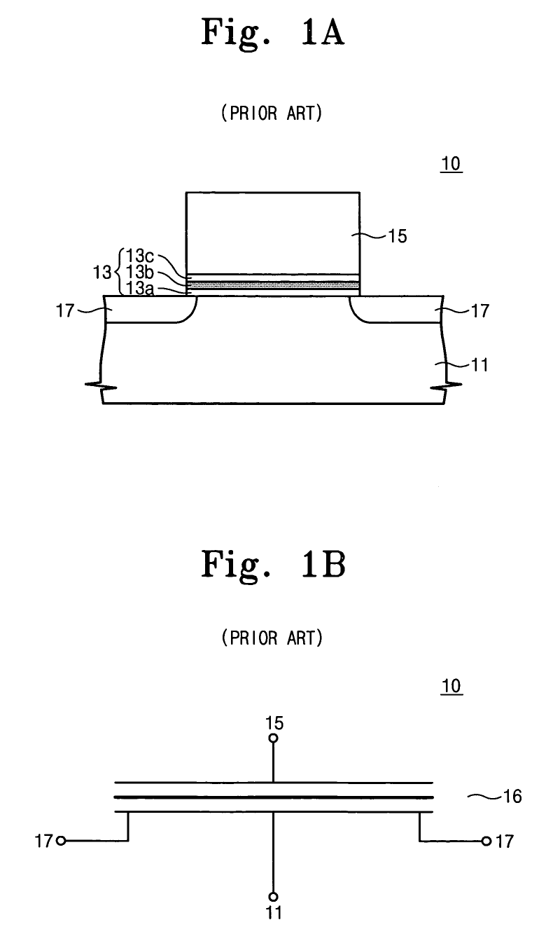

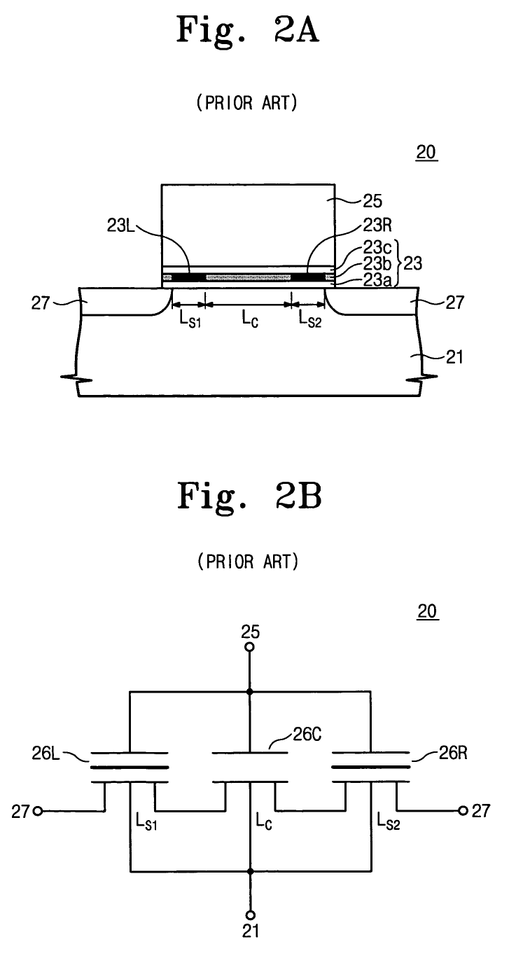

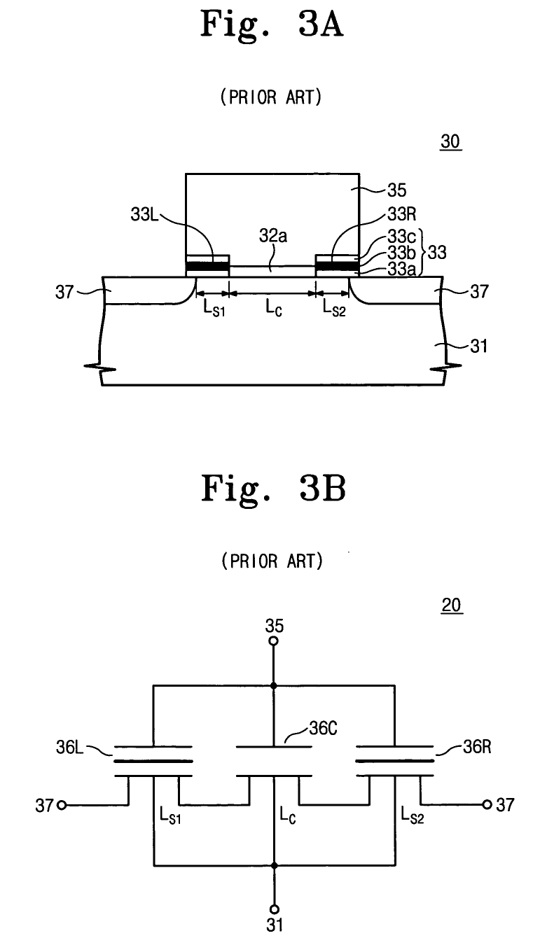

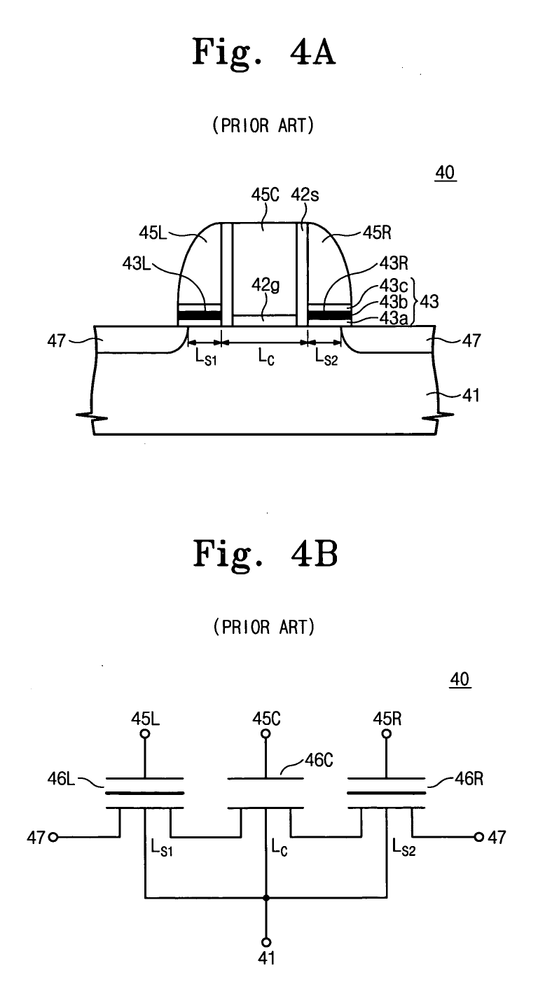

### DETAILED DESCRIPTION OF THE EXEMPLARY EMBODIMENTS

Reference will now be made in detail to the exemplary embodiments of the present invention, examples of which are illustrated in the accompanying drawings. However, the present invention is not limited to the exemplary embodiments illustrated herein after.

Also, like reference numerals in the drawings denote like elements, and thus their overlapping description will be omitted for conciseness.

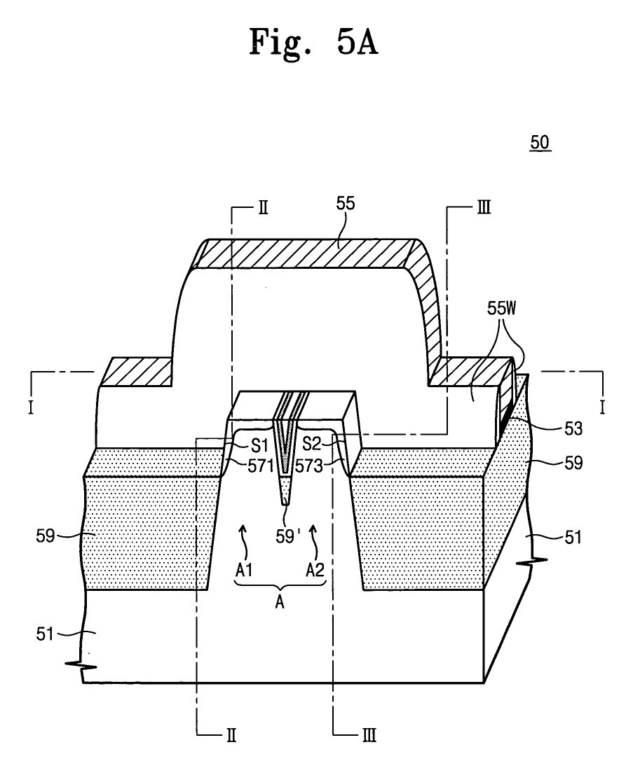

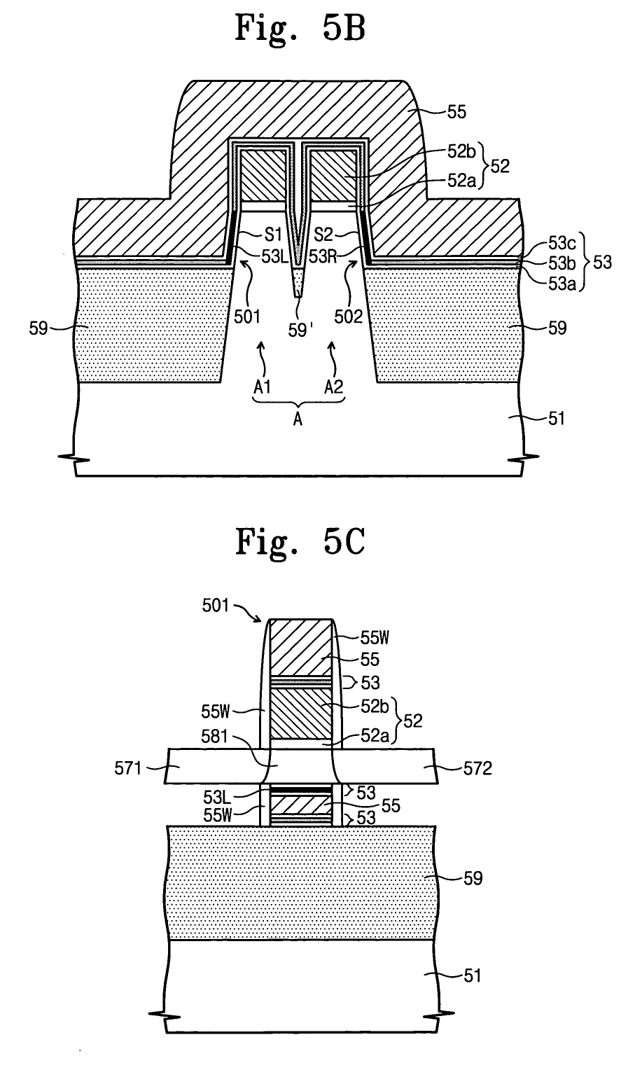

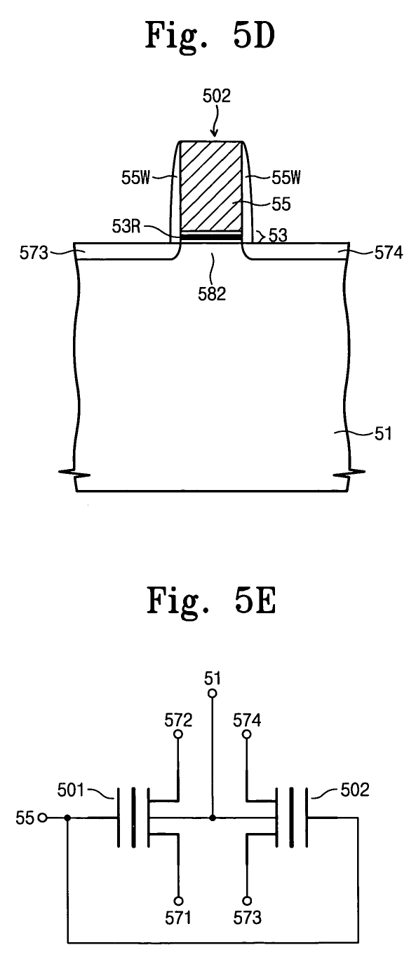

FIG. 5A is a perspective view of a nonvolatile memory device according to a first exemplary embodiment of the present invention, and FIGS. 5B through 5D are sectional views taken along lines I-I, II-II and III-III of FIG. 5A.

Referring to FIGS. 5A through 5D, a nonvolatile memory derive 50 includes a device isolation layer 59 and an active region separation layer 59′ that are spaced apart from each other by a predetermined distance. The device isolation layer 59 defines an active region A protruding from a top surface of a semiconductor substrate 51. The active region separation layer 59′ separates the active region A into first and second active regions A1 and A2 that are spaced apart from each other. The device isolation layer 59 may be formed of an insulating material filling a trench. The active region separation layer 59′ may be formed of an insulating material filling a groove, which is narrower and shallower than the device isolation layer. The device isolation layer 59 and the active region separation layer 59′ may be formed of the same insulating material, such as, for example, a high-density plasma CVD oxide. The active region separation layer 59′ is narrower than the device isolation layer 59. The active region separation layer 59′ may have a width that is smaller than or equal to the minimum linewidth. Also, the first and second active regions A1 and A2 may have a width that is smaller than or equal to the minimum linewidth.

A gate line 55 is provided on and across the first and second active regions A1 and A2 and the device isolation layer 59. The gate line 55 may be formed of a doped polysilicon layer, a metal silicide layer, and/or a metal layer.

Insulating patterns 52 are disposed on the first and second active regions A1 and A2 under the gate line 55. The insulating patterns 52 may be provided only under the gate line 55 such that they are self-aligned with the gate line 55. However, the exemplary embodiments of the present invention is not limited to this structure. For example, the insulating patterns 52 may be provided also on a top portion of the active region that is located at both sides of the gate line 55. The insulating patterns 52 may be a stack of a silicon oxide layer 52a ( e.g., a buffer oxide layer) and a silicon nitride layer 52b (e.g., a hard mask layer).

Both side surfaces of the first and second active regions A1 and A2 are not covered with the device isolation layer 59, the active region separation layer 59′ and the insulating patterns 52. The first and second active regions A1 and A2 have a first side surface S1 and a second side surface S2, respectively. The first and second side surfaces S1 and S2 correspond to the outer sides of the first and second active regions A1 and A2 that are adjacent to the device isolation layer 59.

A memory layer 53 is interposed between the gate line 55 and the first and second active regions A1 and A2. The memory layer 53 is formed at least on the first and second side surfaces S1 and S2. As illustrated in FIGS. 5A through 5D, the memory layer 53 may also be formed on the insulating patterns 52 and the device isolation layer 59 under the gate line 55. The memory layer 53 may include a tunnel oxide layer 53a, a charge storage layer 53b, and an blocking insulating layer 53c.

The tunnel oxide layer 53a may be a thermal oxide layer. The charge storage layer 53b may be a charge trapping layer, for example, having a high-dielectric insulator with a high charge-trapping density. The charge storage layer 53b may be one selected from the group consisting of, for example, hafnium oxide (HfO) layer, lanthanum oxide (LaO) layer, aluminum oxide (Al₂O₃) layer, hafnium aluminum oxide (HfAlO) layer, hafnium silicon oxide (HfSiO) layer, and combinations thereof. Also, the charge storage layer 53b may be a doped polysilicon layer and/or a metallic nanocrystal layer. The blocking insulating layer 53c may be a high-dielectric layer such as, for example, silicon oxide layer, aluminum oxide (Al₂O₃) layer, hafnium oxide (HfO) layer, hafnium aluminum oxide (HfAlO) layer, and/or hafnium silicon oxide (HfSiO) layer.

The thickness of the tunnel insulating layer 53a is determined such that an electric charge can move through the tunnel insulating layer 53a to the charge storage layer 53b during the operation of the nonvolatile memory device 50. The thickness of the blocking insulating layer 53c is determined such that an electric charge cannot move through the blocking insulating layer. For example, the tunnel oxide layer 53a may be a thermal oxide layer with a thickness of about 35 to about 40 angstroms (Å), the blocking insulating layer 53c may be a silicon oxide layer with a thickness of about 100 to about 200 Å, and the charge storage layer 53b may be a silicon nitride layer with a thickness of about 70 to about 150 Å.

The charge storage layers 53b on the first and second side surfaces S1 and S2 can be defined respectively as charge storage regions 53L and 53R that are independently separated from each other.

First through fourth impurity regions 571, 572, 573 and 574 are provided on the first and second sides S1 and S2 such that they are self-aligned with sidewall spacers 55W located at both sides of the gate line 55. The first and second impurity regions 571 and 572 are disposed respectively at both sides of the gate line 55 on the first side surface S1 such that they are spaced apart from each other to define a first channel region 581 therebetween. Likewise, the third and fourth impurity regions 573 and 574 are provided respectively at both sides of the gate line 55 on the second side surface S2 such that they are spaced apart from each other to define a second channel region 582 therebetween. In the first active region A1, the memory layer 53 including the charge storage region 53L, the gate line 55, the first channel region 581, the first impurity region 571, and the second impurity region 572 constitute a first memory cell 501. Likewise, in the second active region A2, the memory layer 53 including the charge storage region 53R, the gate line 55, the second channel region 582, the third impurity region 573, and the fourth impurity region 574 constitute a second memory cell 502. The first and second memory cells 501 and 502 share the gate line 55 with each other.

The memory layer 53 is formed on the insulating pattern 52 between the first and second side surfaces S1 and S2 and a surface of the groove filled with the active region separation layer 59′. Compared with the conventional art, the effective distance between the charge storage regions 53L and 53R is sufficient even when the distance between the impurity regions decreases with the high integration of the memory device. Accordingly, charges stored in the charge storage regions 53L and 53R can be prevented from migrating by diffusion. The charge storage regions 53L and 53R of the memory layer 53 can be independently separated from each other. Therefore, the first and second memory cells 501 and 502 can be independent of each other although they share the gate line 55 with each other. Also, the insulating patterns 52 on the first and second active regions A1 and A2 prevents a channel from being formed at the top portions of the active regions by a voltage applied to the gate line 55. Accordingly, it is possible to effectively prevent a parasitic transistor from occurring at the top portions of the active region.

FIG. 5E is an equivalent circuit diagram of the nonvolatile memory device in FIG. 5A.

Referring to FIGS. 5A through 5E, when predetermined bias voltages are applied to the semiconductor substrate 51, the impurity regions 571 and 572, and the gate line 55, electric charges tunnel through the tunnel oxide layer 53a and are then stored in the charge storage region 53L. Consequently, data is stored in the first memory cell 51. Likewise, when predetermined bias voltages are applied to the semiconductor substrate 51, the impurity regions 573 and 574, and the gate line 55, electric charges tunnel through the tunnel oxide layer 53a and are then stored in the charge storage region 53R. As a result, data is stored in the second memory cell 502.

Electric charges may be injected into the charge storage layer 53b by various mechanisms. First, electric charges may tunnel through the tunnel oxide layer 53a and be injected into the charge storage layer 53b. When the thickness of the tunnel oxide layer 53a is smaller than about 30 Å, electric charges are injected using a direct tunneling technique. When the thickness of the tunnel oxide layer 53a is larger than about 30 Å, electric charges are injected through a Fowler-Nordheim (FN) tunneling mechanism. In a band-to-band tunneling mechanism, hot holes (HHs) generated in the impurity region overlapping the gate are injected into the charge storage layer 53b by an electric field applied to the gate. Alternatively, channel-hot-electrons (CHEs), which are generated in the channel region by a high voltage applied between the source and the drain, overcomes a potential barrier of the tunnel oxide layer 53a and are injected into the charge storage layer 53b.

According to the first exemplary embodiment, a unit memory device has memory cells corresponding to two independent memory sites. Therefore, it is possible to implement a multi-bit memory device. When 3-level or 4-level logic data, instead of 2-level logic data ‘0’ and ‘1’, are stored in one memory cell, 3-bit or 4-bit data can be stored in a unit memory device.

The 4-level logic data can be obtained by dividing a threshold voltage, which is induced by electric charges stored in the charge storage layer, into four sections and allocating four data values ‘00’, ‘01’, ‘10’ and ‘11’ to the four sections, respectively. As one charge storage layer can store 2-bit data, the structure according to the first exemplary embodiment makes it possible to store 4-bit data in a unit memory device.

The 3-level logic data can be obtained by dividing the threshold voltage into three sections and allocating three data values to the three sections, respectively. At this point, two charge storage layers should be paired. Therefore, according to the structure of the first exemplary embodiment where two memory cells constitute one unit memory device, 3-bit data can be stored in the unit memory device. As the 3-level logic has more data storage states than the 2-level logic, it can provide a higher integration level. Also, as the 3-level logic is larger in an interval between threshold voltage sections than the 4-level logic, it can provide a higher reliability and can reduce the programming time.

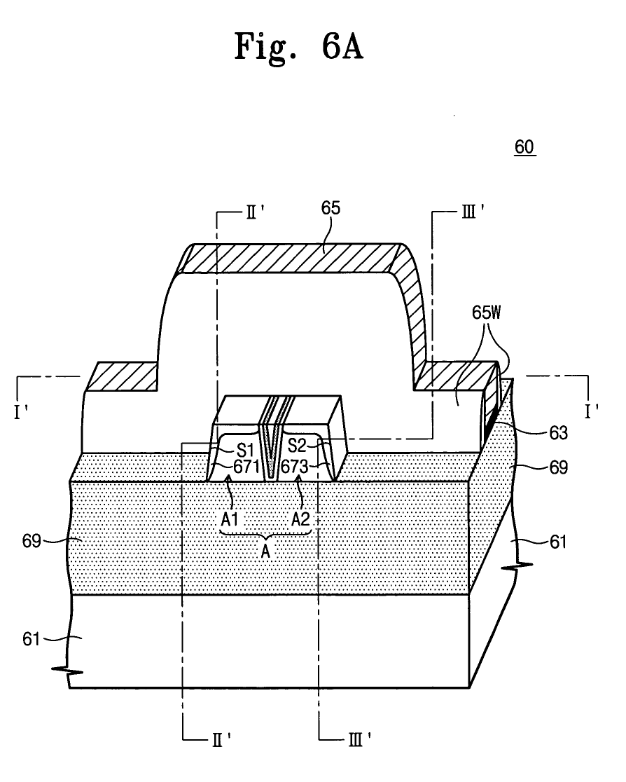

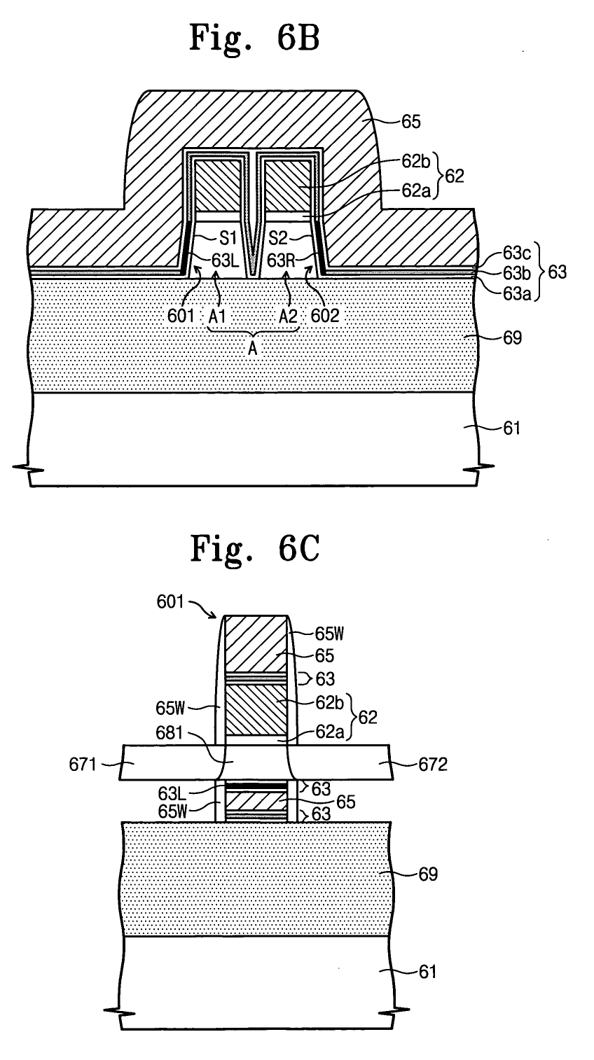

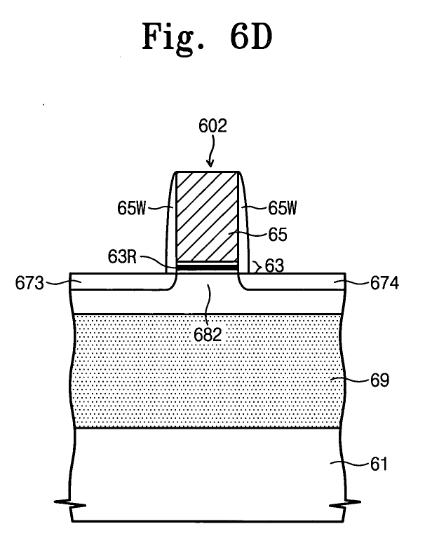

FIG. 6A is a perspective view of a nonvolatile memory device according to a second exemplary embodiment of the present invention, and FIGS. 6B through 6D are sectional views taken along lines I′-I′, II′-II′ and III′-III′ of FIG. 6A.

Referring to FIGS. 6A through 6D, unlike the nonvolatile memory device 50 of FIGS. 5A through 5E, nonvolatile memory device 60 includes an SOI (silicon on insulator) substrate having a buried insulating layer 69 and a substrate 61. An active layer A protrudes from a top surface of the SOI substrate 61. The active layer A is separated into a first active region A1 and a second active region A2 that are spaced apart from each other by a narrow and shallow groove. That is, the nonvolatile memory device 60 can be understood as a structure that the device isolation layer 59 of the nonvolatile memory device 50 extends under the active region A and the extended device isolation layer is exposed in a groove to form the active region separation layer 59′. Accordingly, the device isolation layer 59 and the active region separation layer 59′ correspond to a buried insulating layer 69 of the second embodiment. In FIGS. 6A through 6D, reference numerals whose descriptions are omitted correspond to those in FIGS. 5A through 5D. For example, reference numerals 65W, 63L, 62 and 671 correspond to 55W, 53L, 52 and 571, respectively.

According to the second exemplary embodiment, the nonvolatile memory device 60 can store multi-bit data while having the advantages of the SOI structure.

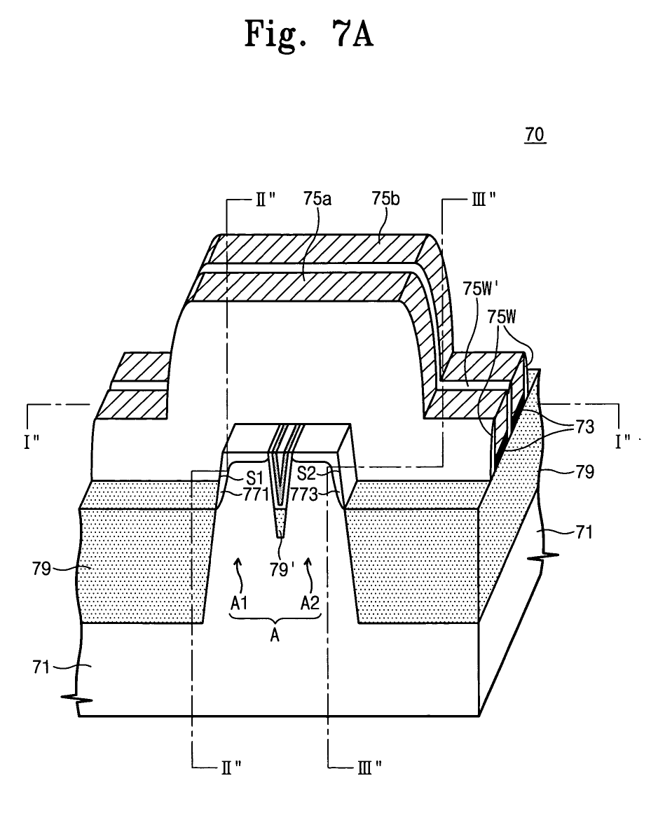

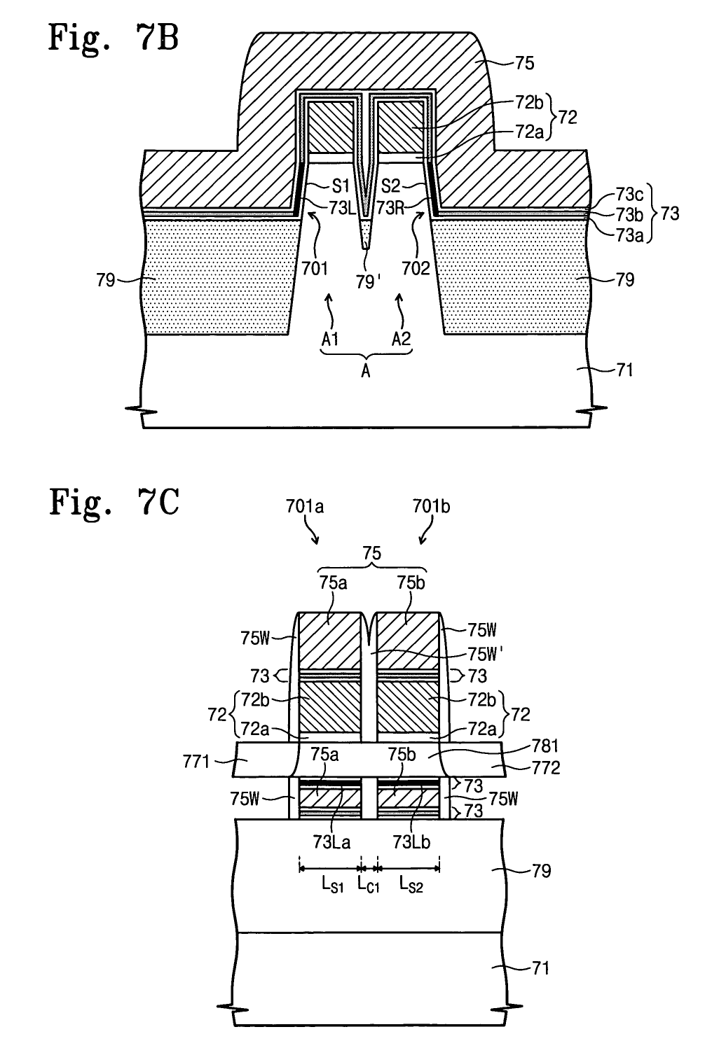

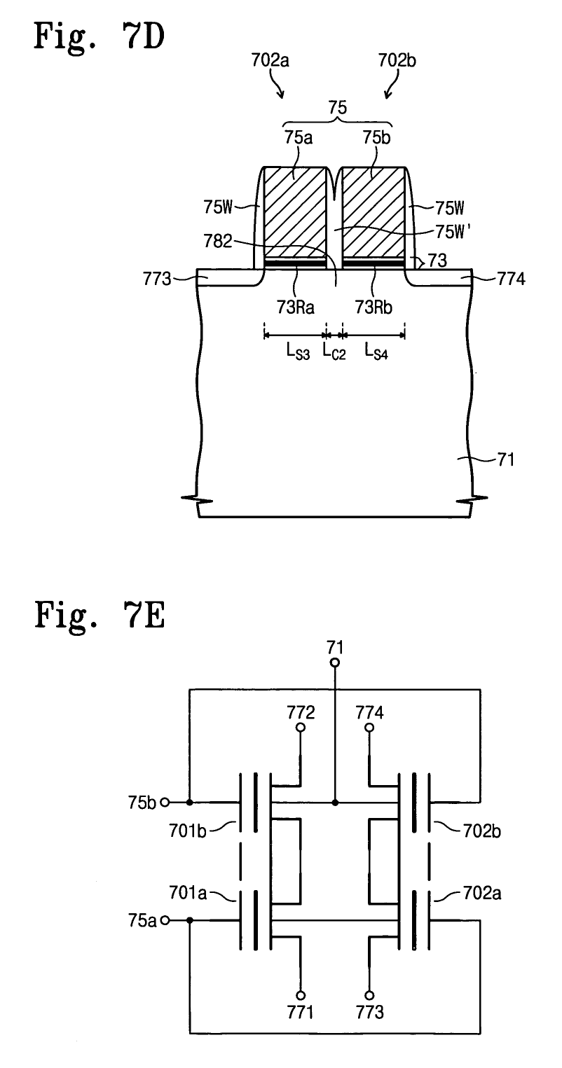

FIG. 7A is a perspective view of a nonvolatile memory device according to a third exemplary embodiment of the present invention, and FIGS. 7B through 7D are sectional views taken along lines I″-I″, II″-II″ and III″-III″ of FIG. 7A.

Referring to FIGS. 7A through 7D, unlike the nonvolatile memory device 50, nonvolatile memory device 70 has a gate line 75 including a pair of gate electrodes 75a and 75b that are spaced in parallel to each other.

A first memory cell will now be described with reference to FIG. 7C illustrating a first side surface S1. The first memory cell includes first and second impurity regions 771 and 772 and a first channel region 781. The first and second impurity regions 771 and 772 are formed over a semiconductor substrate 70 such that they are spaced apart from each other by a predetermined distance. The first channel region 781 is provided between the first and second impurity regions 771 and 772. The first channel region 781 with the first memory cell includes a plurality of sub-channel regions L_{S1}, L_{C1} and L_{S2}. First and second sub-memory cells 701a and 701b, which are separated by a barrier insulating layer 75W′, are provided respectively on the sub-channel regions L_{S1} and L_{S2}. Accordingly, the first memory cell includes a pair of sub-memory cells 701a and 701b that share the first and second impurity regions 771 and 772 and are controlled by a pair of gate electrodes 75a and 75b.

A second memory cell will now be described with reference to FIG. 7D illustrating a second side surface S2. The second memory cell includes third and fourth impurity regions 773 and 774 and a second channel region 782. The third and fourth impurity regions 773 and 774 are formed over the semiconductor substrate 70 such that they are spaced apart from each other by a predetermined distance. The second channel region 782 is disposed between the third and fourth impurity regions 773 and 774. The second channel region 782 with the second memory cell includes a plurality of sub-channel regions L_{S3}, L_{C2} and L_{S4}. Third and fourth sub-memory cells 702a and 702b, which are separated by the barrier insulating layer 75W′, are disposed respectively on the sub-channel regions L_{S3} and L_{S4}. Accordingly, the second memory cell includes a pair of sub-memory cells 702a and 702b that share the third and fourth impurity regions 773 and 774 with each other and are controlled by a pair of gate electrodes 75a and 75b.

Each of the first and second sub-memory cells 701a and 701b of the first memory cell includes gate electrodes 75a and 75b and charge storage regions 73La and 73Lb that are sequentially stacked on the first side surface S1 on the sub-channel regions L_{S1} and L_{S2}. The first sub-channel region L_{S1} is defined under the first sub-memory cell 701a, the second sub-channel region L_{S2} is defined under the second sub-memory cell 701b, and the center channel region L_{C1} is defined under the barrier insulating layer 75W′. The first sub-channel region L_{S1} is controlled by the gate electrode 75a ( e.g., a first gate) of the first sub-memory cell 701a, the second sub-channel region L_{S2} is controlled by the gate electrode 75b (e.g., a second gate) of the second sub-memory cell 701b, and the center channel region L_{C1} is controlled by the first gate 75a or the second gate 75b. That is, the center channel region L_{C1} is controlled by a coupling capacitor that is induced by the effect of a fringe electric field due to the gate electrodes 75a and 75b. The sub-memory cells 702a and 702b of the second memory cell may be constructed in the same manner as the sub-memory cells 701a and 701b of the first memory cell.

According to exemplary embodiments of the present invention, the sub-memory cells are symmetrical to each other. For example, for the first sub-memory cell 701a, the first impurity region 771 and the second impurity region 772 serve as a source region and a drain region, respectively. On the contrary, for the second sub-memory cell 701b, the first impurity region 771 and the second impurity region 772 serve as a drain region and a source region, respectively.

When electric charges (e.g., electrons) are injected into the charge storage layer of the memory cell, electric charges, for example, are not accumulated in the barrier insulating layer 75W′ interposed between the first and second sub-memory cells 701a and 701b and between the third and fourth sub-memory cells 702a and 702b. To this end, in the exemplary embodiments of the present invention, an insulating layer is used as the barrier insulating layer 75W′. When electric charges are accumulated in the barrier insulating layer 75W′ during a program operation, the program efficiency decreases. The accumulated electric charges may affect a threshold voltage of the memory cell during a read operation, and may increase an erase time that is taken to completely remove the accumulated electric charges during the erase operation. To reduce the coupling between the gate electrodes 75a and 75b, the barrier insulating layer between the gate electrodes 75a and 75b may have a low dielectric constant. Therefore, the barrier insulating layer 75W′ may be, for example, a silicon oxide layer. For a high integration level, the barrier insulating layer 75W′ is, for example, as thin as possible. For example, the width of the barrier insulating layer 75W′ is smaller than the thickness of a memory layer 73. To enhance the control capability of the gate with respect to the sub-channel regions L_{C1}, L_{C2}, L_{S3} and L_{S4}, the barrier insulating layer between the memory layers 73 may have a high dielectric constant. Reference numerals whose descriptions are omitted correspond to those in FIGS. 5A through 5D. For example, reference numerals 75W and 79 correspond to 55W and 59, respectively.

FIG. 7E is an equivalent circuit diagram of the nonvolatile memory device in FIG. 7A.

Referring to FIGS. 7A through 7E, when predetermined bias voltages are applied to the semiconductor substrate 71, the impurity regions 771 and 772, and the gate electrodes 75a and 75b, electric charges tunnel through the tunnel oxide layer 73a (or overcome the potential barrier of the tunnel oxide layer 73a) and are stored in the charge storage regions 73La and 73Lb. In which of the charge storage regions 73La and 73Lb the electric charges are to be stored is determined according to the voltages applied to the gate electrodes 75a and 75b. Likewise, when predetermined bias voltages are applied to the semiconductor substrate 71, the impurity regions 773 and 774, and the gate electrodes 75a and 75b, electric charges tunnel through the tunnel oxide layer 73a (or overcome the potential barrier of the tunnel oxide layer 73a) and are stored in the charge storage regions 73Ra and 73Rb. In this way, respective data can be independently stored in four memory sites.

When the 3-level or 4-level logic structure described in the first exemplary embodiment are used, 6-bit or 8-bit data can be stored in one memory device.

A large memory array may be used to apply the nonvolatile memory devices of the first through third exemplary embodiments to an actual product. As described above, the unit memory devices of exemplary embodiments of the present invention include two or four independent memory cells, thereby making it possible to package more memory cells. For example, the nonvolatile memory device of exemplary embodiments of the present invention may be implemented in a memory array with a proper structure for NAND or NOR flash memory devices.

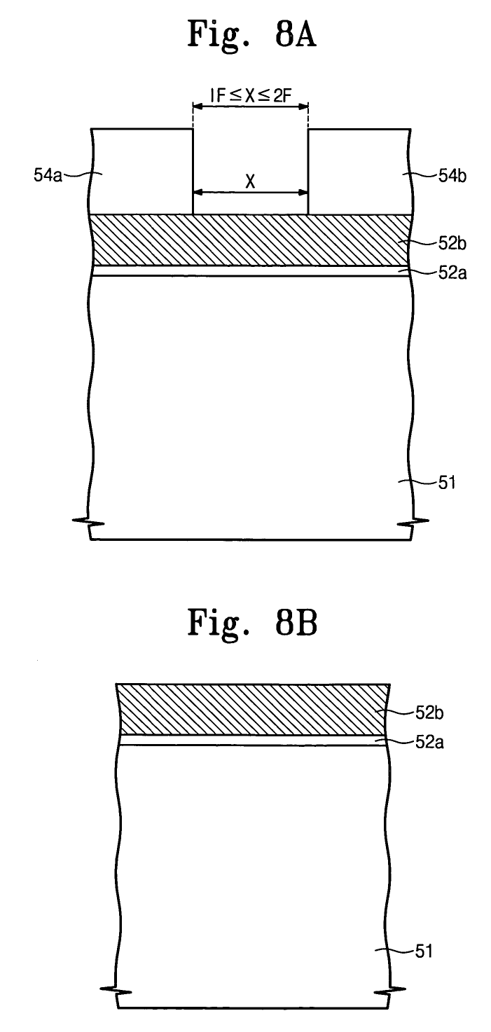

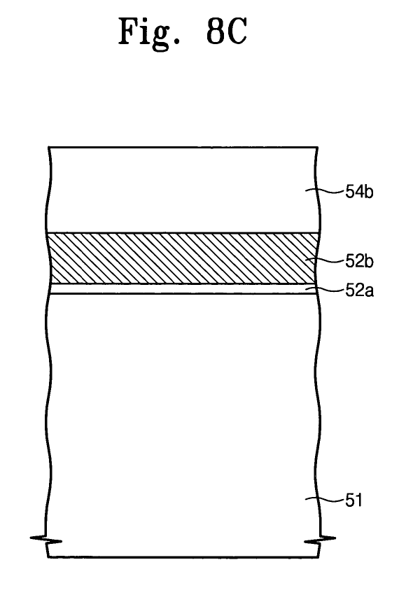

A method of fabricating the N-channel nonvolatile memory device according to the first exemplary embodiment of FIGS. 5A through 5E will now be described with reference to FIGS. 8 through 17.

FIGS. 8 through 17 are sectional views illustrating a method of fabricating a nonvolatile memory device according to a first exemplary embodiment of the present invention. FIGS. 8A through 17A, 8B through 17B and 8C through 17C are sectional views taken along lines I-I, II-II and III-III of FIG. 5A, respectively.

Referring to FIGS. 8A through 8C, a hard mask layer is formed on a P-type semiconductor substrate 51. The hard mask layer may comprise, for example, a silicon oxide layer, silicon nitride layer, and/or silicon nitride layer 52b on a buffer oxide layer 52a.

Before the forming of the hard mask layer, N-type impurity ions may be implanted into the P-type semiconductor substrate 51 such that an N-channel memory cell has a negative threshold voltage, thereby forming an impurity diffusion layer of the nonvolatile memory device of FIG. 5A. In the case of the N-channel memory cell, arsenic or phosphor ions may be implanted at an energy of about 30 to about 50 keV at a dose of about 1×10¹² to about 1×10¹³ atoms/cm² to form the impurity diffusion layer. Similarly, in the case of a P-channel memory cell, boron ions may be implanted at an energy of about 30 to about 50 keV at a dose of about 1×10¹² to 1×10¹³ atoms/cm² to form the impurity diffusion layer.

A dummy layer is formed on the hard mask layer. The dummy layer may comprise photosensitive layer or undoped polysilicon layer with a high etch selectivity with respect to the hard mask layer 52b. A photolithography process is performed to form a first dummy pattern 54a and a second dummy pattern 54b on the hard mask layer 52b. A distance X between the first and second dummy patterns 54a and 54b may be larger than the minimum linewidth F and smaller than 2F (F≦X≦2F).

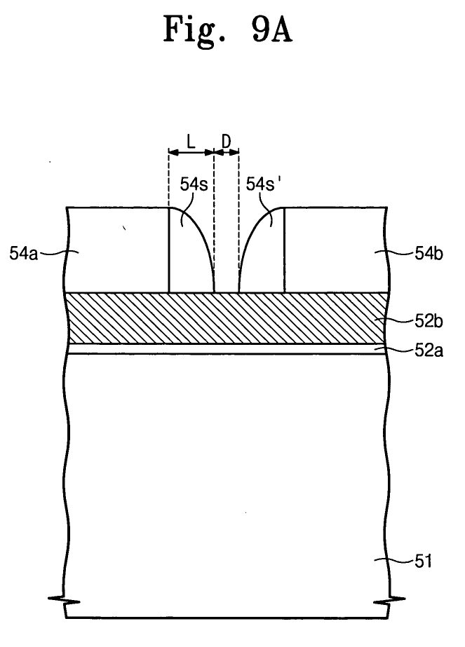

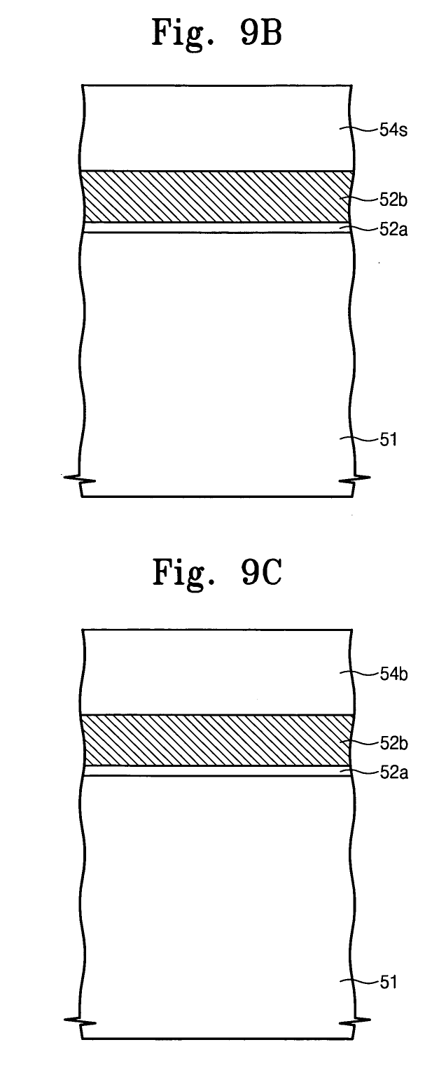

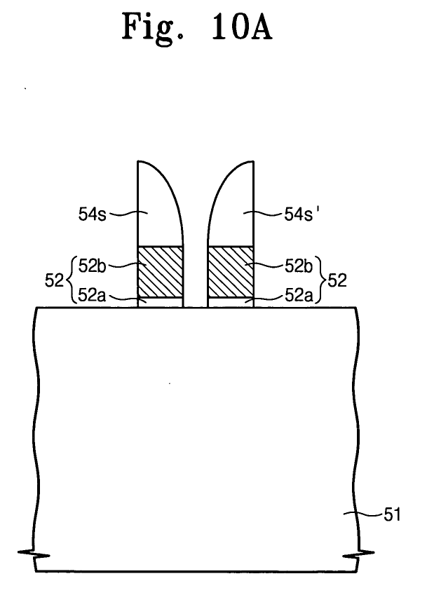

Referring to FIGS. 9A through 9C, spacers 54s and 54s′ are formed on sidewalls of the first and second dummy patterns 54a and 54b. The spacers 54s and 54s′ may be formed by depositing a material with an etch selectivity with respect to the dummy patterns and then performing an etch-back process on the resulting structure. The spacers 54s and 54s′ may be formed of a material with an etch selectivity with respect to the hard mask layer 52b. For example, when the hard mask layer 52b is formed of a silicon oxide layer, the spacers 54s and 54s′ may be formed of a silicon nitride layer. On the other hand, when the hard mask layer 52b is formed of a silicon nitride layer, the spacers 54s and 54s′ may be formed of a silicon oxide layer.

The width L of each of the spacers 54s and 54s′ is smaller than half of the distance X (L<(X/2)). Accordingly, a distance D between the spacer 54s of the dummy pattern 54a and the spacer 54s′ of the dummy pattern 54b is smaller than the minimum linewidth F (D<F). The distance between a pair of the spacers 54s and 54s′ determines the minimum distance between active regions adjacent to each other, which will be described in detail later. Accordingly, the memory cell can be formed such that it has the gap and width smaller than the allowable minimum linewidth F of a photolithography process.

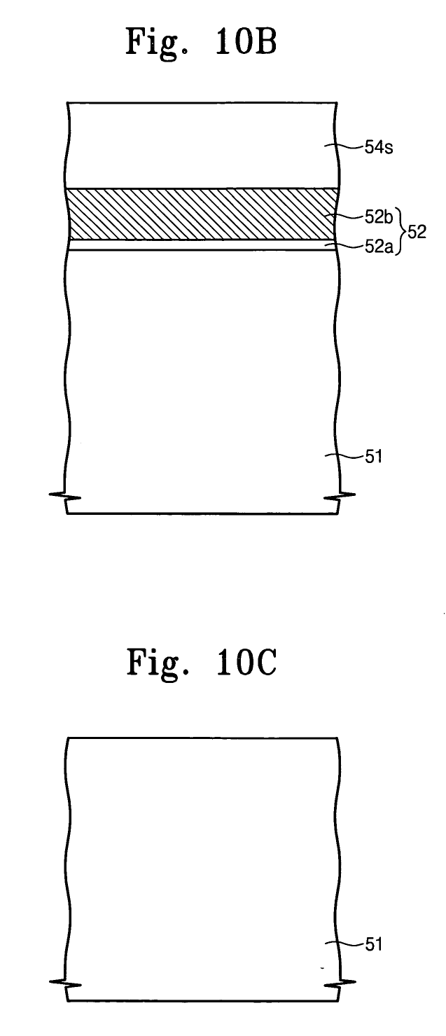

Referring to FIGS. 10A through 10C, the first and second dummy patterns 54a and 54b are removed to expose the hard mask layer 52b. Thereafter, the hard mask layer 52b and the buffer oxide layer 52a are etched using the spacers 54s and 54s′ as an etch mask, thereby forming hard mask patterns 52 ( e.g., insulating layer patterns) having substantially the same width L as the spacer. As the hard mask patterns 52 are formed under the spacers 54s and 54s′, they have the same width (L) and distance (D) as those of is the spacers 54s and 54s′.

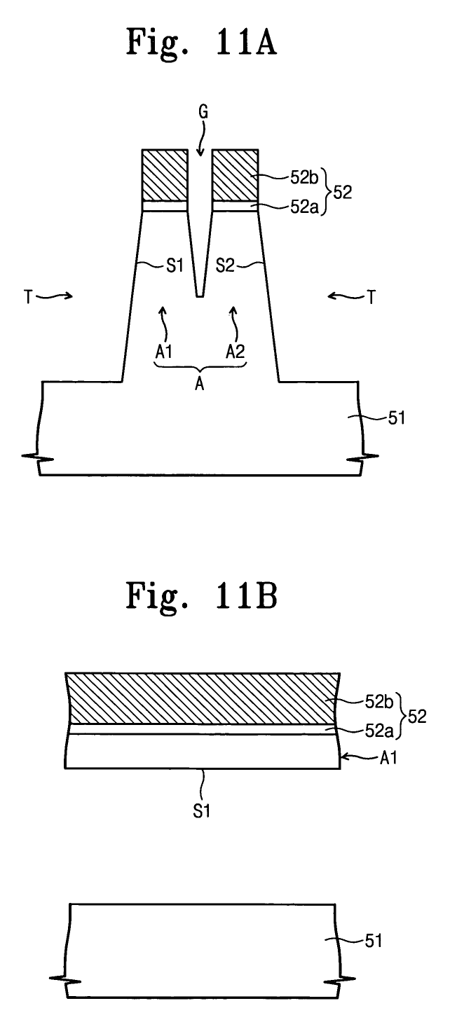

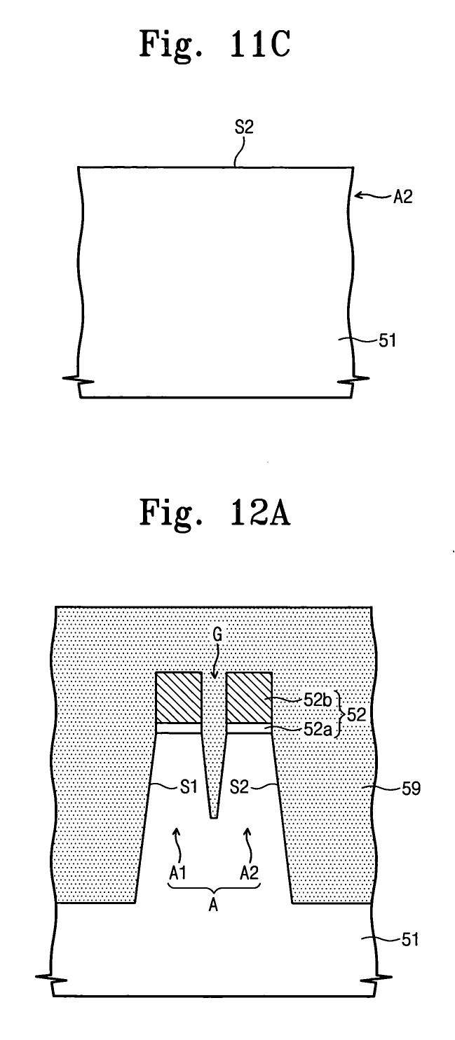

Referring to FIGS. 11A through 11C, the spacers 54s and 54s′ are removed to expose hard mask patterns 52 that face each other and has a narrow width L. Thereafter, the semiconductor substrate 51 is etched using the mask patterns 52 as an etch mask. Alternatively, the etching of the semiconductor substrate 51 may be performed without removing the spacers 54s and 54s′.

A narrow and shallow groove G is formed on the semiconductor substrate 51 between the hard mask patterns 52, while wide and deep trenches T are formed on the semiconductor substrate at both sides of the hard mask patterns 52. The width of the groove G is determined by the distance D between the spacers 54s and 54s′. An active region A is formed between the trenches T in such a way that it is separated into a first active region A1 and a second active region A2 by the groove G. The outer sides of the first and second active regions A1 and A2 correspond to a first side surface S1 and a second side surface S2, respectively.

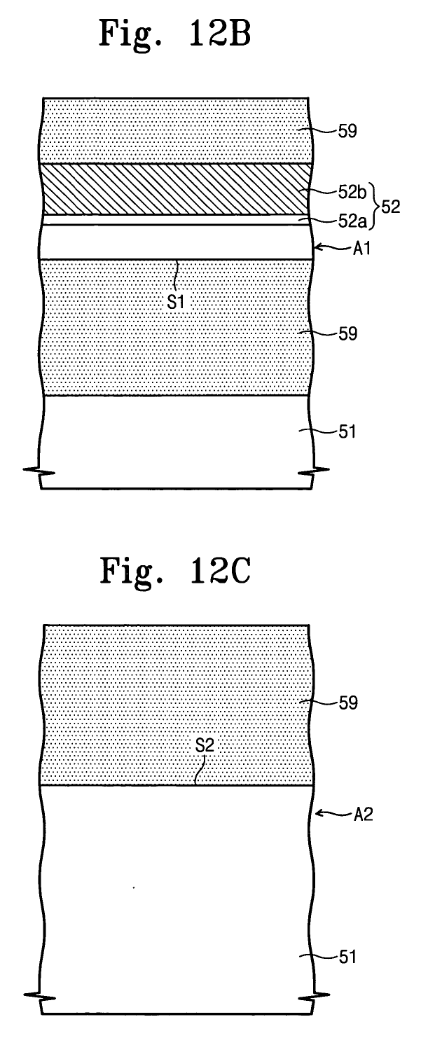

Referring to FIGS. 12A through 12C, an insulating layer is formed to fill the groove G and the trenches T. The insulating layer may be formed of an USG (undoped silicate glass) oxide or a high-density plasma CVD oxide that can fill the narrow groove without formation of voids.

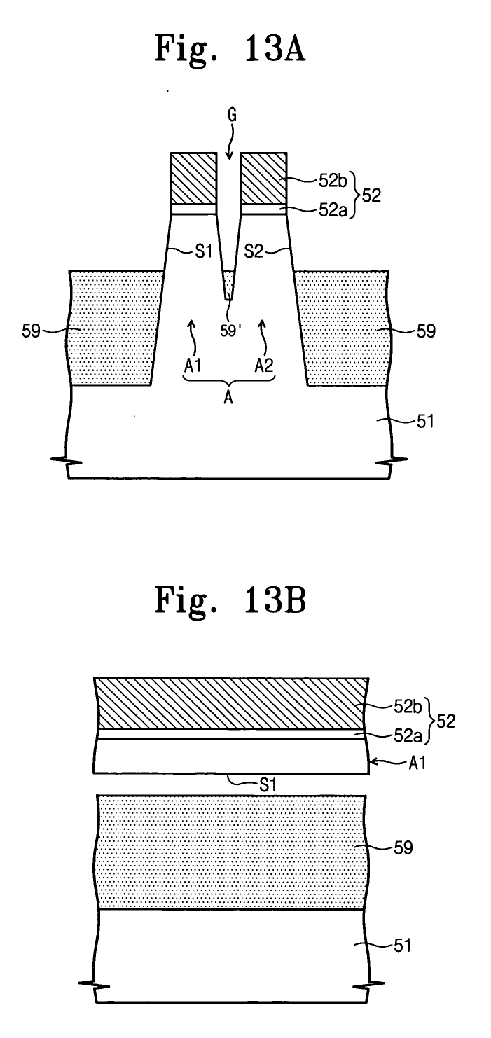

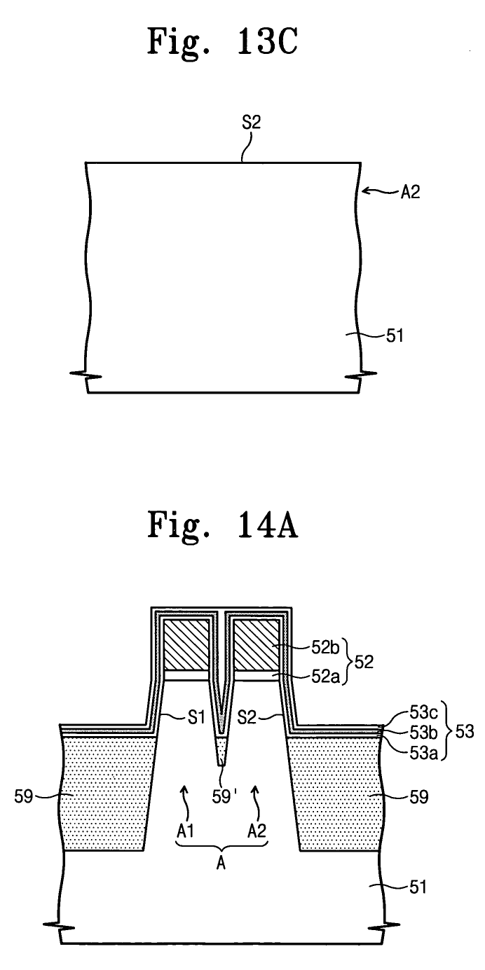

Referring to FIGS. 13A through 13C, the insulating layer is etch-backed to expose a protruding portion of the active region A. As a result, a device isolation layer 59 is formed in the trenches T and an active region separation layer 59′ is formed in the groove G. The device isolation layer 59 is formed in such a way that it exposes the first and second side surfaces S1 and S2 which are adjacent to the upper outer sides of the first and second active regions A1 and A2. Although it is illustrated that the upper surfaces of the active region separation layer 59′ and the device isolation layer 59 have the same height, exemplary embodiments of the present invention are not limited to this. That is, as an etch rate in the groove G decreases as the width of the groove G decreases, the upper surface of the active region separation layer 59′ may be higher than the upper surface of the device isolation layer 59.

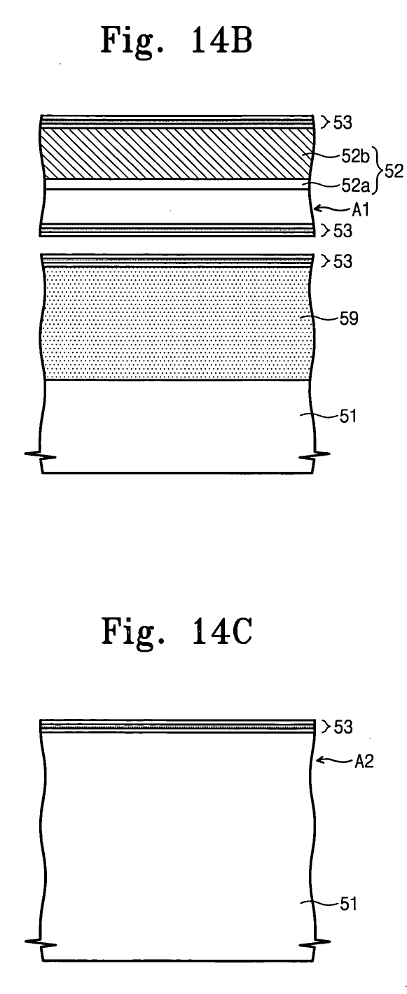

Referring to FIGS. 14A through 14C, a memory layer 53 is formed on the resulting structure on the semiconductor substrate 51. Although it is illustrated that the memory layer 53 is uniformly formed on the groove surface as well as the first and second side surfaces S1 and S2, the exemplary embodiments of the present invention are not limited to this. That is, the memory layer 53 may be formed to have defects in the groove, so that the memory layer 53 on the first side S1 and the memory layer 53 on the second side surface S2 may be physically isolated from each other.

The memory layer 53 includes a tunnel oxide layer 53a, a charge storage layer 53b, and an isolation insulating layer 53c that are sequentially stacked. The tunnel oxide layer 53a may be a thermal oxide layer formed to a thickness of about 35 to about 40 Å by a thermal oxidation process or a thin film deposition process. The charge storage layer 53b may be a silicon nitride layer formed to a thickness of about 70 to about 150 Å by a thin film deposition process. The buried insulating layer 53c may be a silicon oxide layer formed to a thickness of about 100 to about 200 Å by a thin film deposition process.

The charge storage layer 53b may comprise a conducting or insulating material with a charge storage region, instead of using the silicon nitride layer. For example, the charge storage layer 53b may comprise an insulator with a high chart trap density, such as, for example, aluminum oxide (Al₂O₃) layer, hafnium oxide (HfO) layer, hafnium aluminum oxide (HfAlO) layer, and hafnium silicon oxide (HfSiO) layer, or may comprise doped polysilicon or metallic nanocrystal.

The buried insulating layer 53c may be formed using a high-dielectric insulator such as, for example, aluminum oxide (Al₂O₃) layer, hafnium oxide (HfO) layer, hafnium aluminum oxide (HfAlO) layer, and hafnium silicon oxide (HfSiO) layer, instead of using silicon oxide layer.

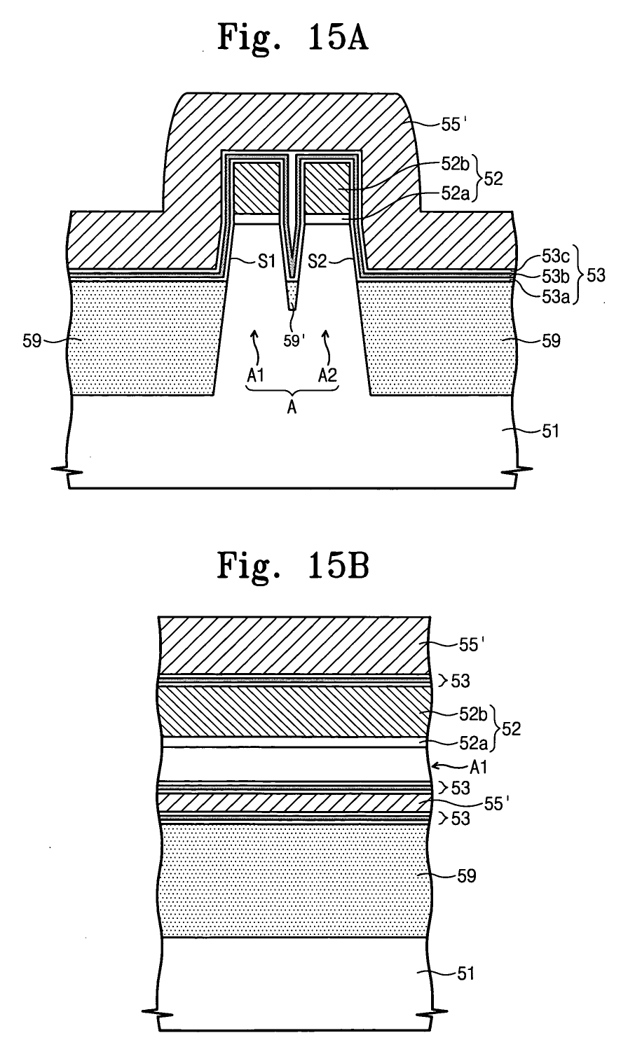

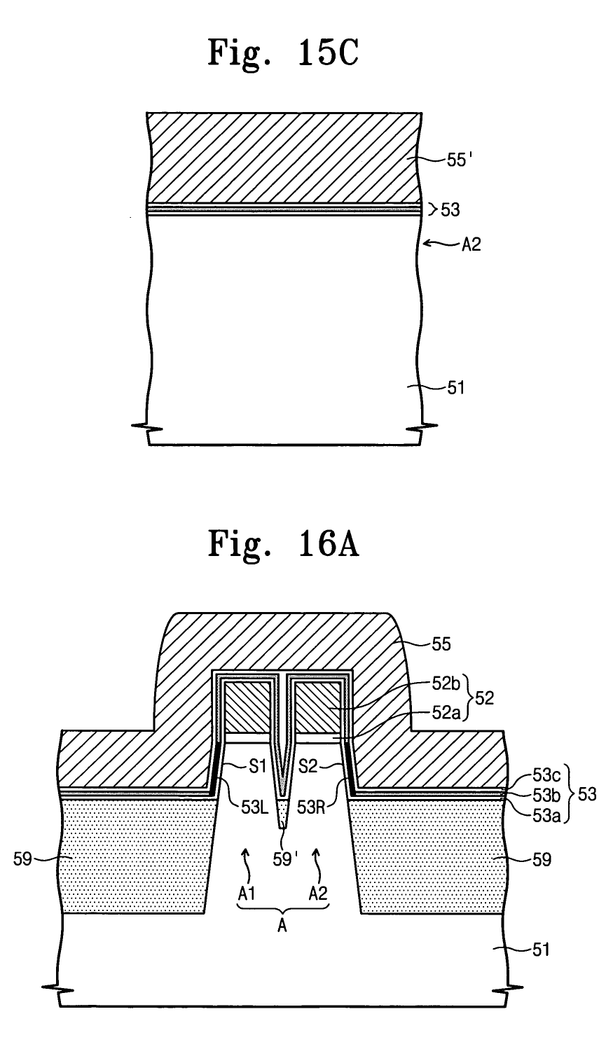

Referring to FIGS. 15A through 15C, a gate conductive layer 55′ is formed on the memory layer 53. The gate conductive layer 55′ may be formed of doped polysilicon. Also, instead of implanting impurity ions into the semiconductor substrate 51, the gate conductive layer 55′ may be of metallic material or properly-doped polysilicon so that a memory cell has a negative threshold voltage. Also, the threshold voltage of the memory cell may be adjusted to a negative value by using a combination of ion implantation for an impurity diffusion layer and ion implantation for doped polysilicon gate.

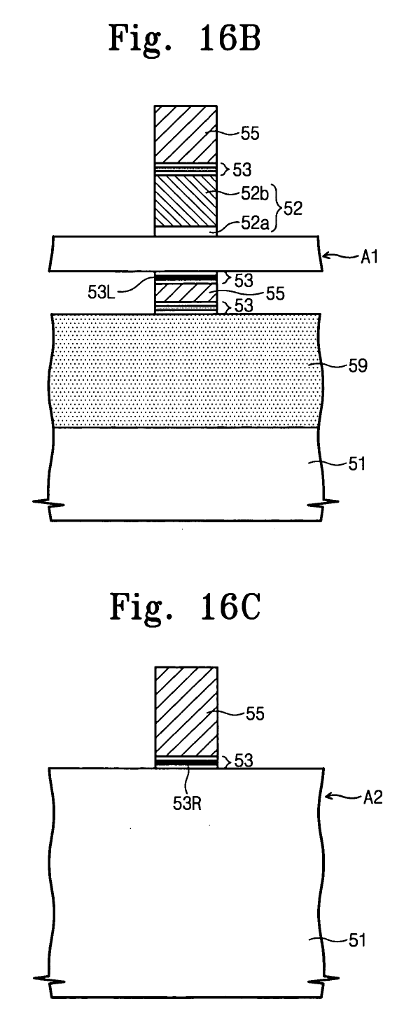

Referring to FIGS. 16A through 16C, the gate conductive layer 55′ is patterned to form a gate line 55 that crosses the first active region A1, the second active layer A2 and the device isolation layer 59. Simultaneously with the patterning of the gate conductive layer 55′, the memory layer 53 may be etched to expose the surfaces of the hard mask pattern 52 and the device isolation layer 59. Charge storage regions 53L and 53R, which correspond to a memory layer under the gate line 55, are defined on the first and second active regions A1 and A2. A wet-etching process may be performed to remove the entire hard mask pattern 52 or a portion (e.g., a silicon nitride pattern 52b) of the hard mask patterns 52 (See FIG. 5A).

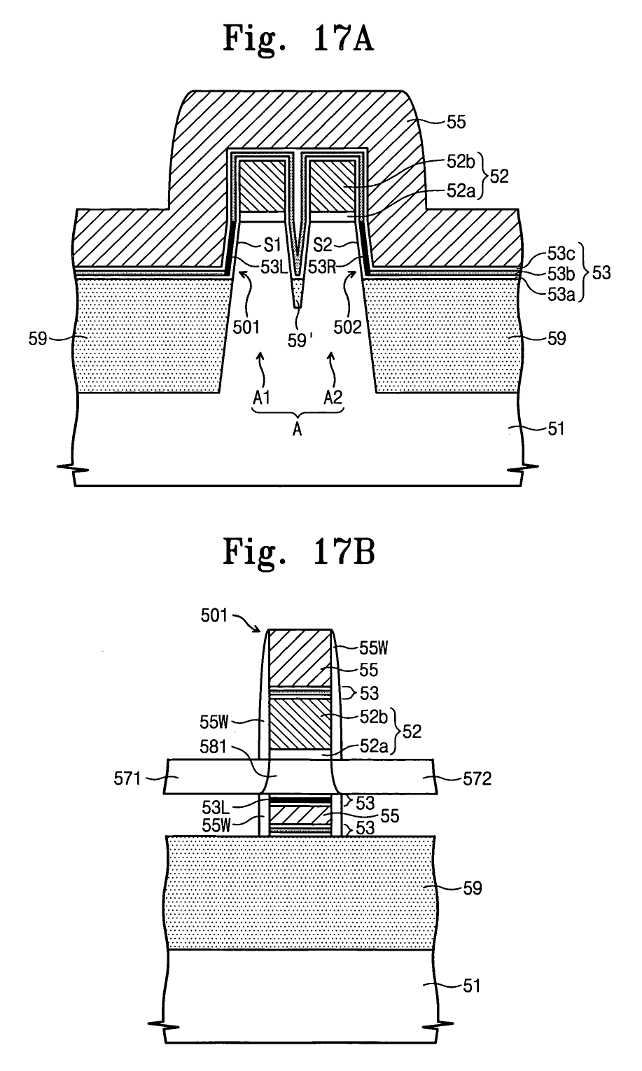

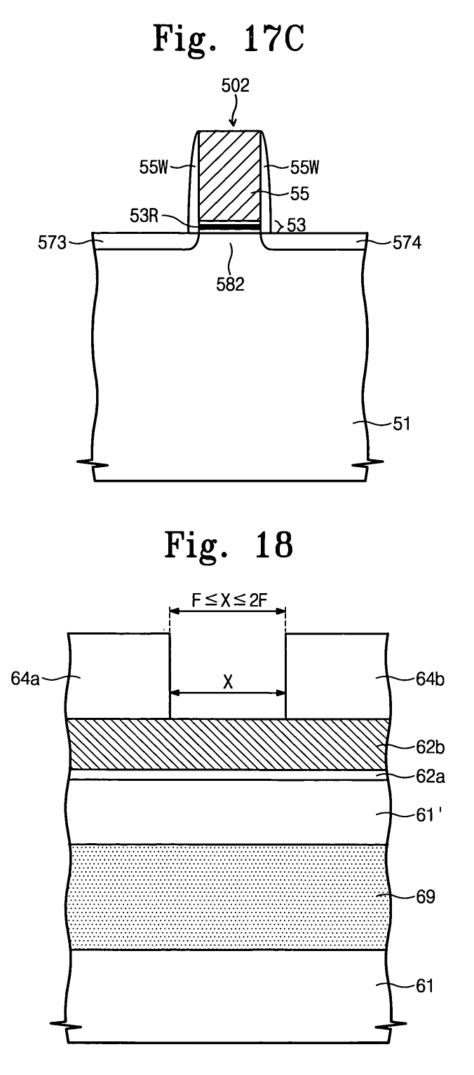

Referring to FIGS. 17A through 17C, an insulating material is deposited, and the resulting structure is etch-backed to form spacers 55W on both sidewalls of the gate line 55. High-concentration impurity ions are implanted to form impurity regions in active regions at both sides of the gate line 55. The impurity regions are formed by implanting arsenic or phosphor ions at an energy of about 30 to about 50 keV at a dose of about 1×10¹⁵ to 5×10¹⁵ atoms/cm² and heat-treating the resulting structure. Similarly, for a P-channel memory cell, the impurity regions are formed by implanting arsenic or phosphor ions at an energy of about 30 to about 50 keV at a dose of about 1×10¹⁵ to 5×10¹⁵ atoms/cm² and heat-treating the resulting structure.

An impurity ion implantation process may be further performed before the forming of the spacers 55W. That is, low-concentration impurity regions are formed in active regions at both sides of the gate line 55 using the gate line of FIGS. 16A and 16C as a mask. The low-concentration impurity regions are formed by implanting arsenic or phosphor ions at an energy of about 10 to about 30 keV at a dose of about 5×10¹⁴ to 1×10¹⁵ atoms/cm² and heat-treating the resulting structure. Similarly, for a P-channel memory cell, the low-concentration impurity regions are formed by implanting arsenic or phosphor ions at an energy of about 10 to about 30 keV at a dose of about 5×10¹⁴ to 1×10¹⁵ atoms/cm² and heat-treating the resulting structure.

As a result of the above ion implantation process, a first impurity region 571, a second impurity region 572, and a first channel region 581 therebetween are formed at the first side surface S1, and a third impurity region 573, a fourth impurity region 574, and a second channel region 582 therebetween are formed at the second side surface S2.

A first memory cell 501 and a second memory cell 502 are formed in the first active region A1 and the second active region A2, respectively.

Thereafter, an interlayer insulating layer is formed on the semiconductor substrate 51 including the memory cells 501 and 502. Contact holes are formed to expose the impurity regions 571, 572, 573 and 574. The contact holes are filled with a contact plug material to connect the impurity regions 571, 572, 573 and 574 to an upper line.

The nonvolatile memory device fabricated by the above method uses the side portion of the trench as the channel region, thereby making it possible to effectively prevent the difficulty created at an edge portion of the trench isolation structure of the conventional nonvolatile memory device. For example, according to the fabrication method of the present exemplary embodiment, as the insulating material filling the trench is etch-backed to form the upper portion of the trench device isolation layer, no defect is formed at the first and second side surfaces S1 and S2. Accordingly, the above-mentioned difficulty in conventional nonvolatile memory devices which occurs at the edge of the trench is significantly reduced with exemplary embodiments of the present invention to improve the characteristics and its distribution of the nonvolatile memory device.

A method of fabricating the N-channel nonvolatile memory device according to the second exemplary embodiment of FIGS. 6A through 6D will now be described with reference to FIGS. 18 through 21.

FIGS. 18 through 21 are sectional views illustrating a method of fabricating a nonvolatile memory device according to a second exemplary embodiment of the present invention. FIGS. 18 through 21 are sectional views taken along a line I′-I′ of FIG. 6A.

Referring to FIG. 18, a hard mask layer is formed on a P-type semiconductor substrate 61 with a buried insulating layer 69. The hard mask layer may comprise, for example, silicon nitride layer, silicon oxide layer, and/or silicon nitride layer 62b on a buffer oxide layer 62a.

Before the forming of the hard mask layer 62b, N-type impurity ions may be implanted into the P-type semiconductor substrate 61 such that an N-channel memory cell has a negative threshold voltage, thereby forming an impurity diffusion layer of the nonvolatile memory device of FIG. 6A. In the case of the N-channel memory cell, arsenic or phosphor ions may be implanted at an energy of about 30 to about 50 keV at a dose of about 1×10¹² to 1×10¹³ atoms/cm² to form the impurity diffusion layer. Similarly, in the case of a P-channel memory cell, boron ions may be implanted at an energy of about 30 to about 50 keV at a dose of about 1×10¹² to 1×10¹³ atoms/cm² to form the impurity diffusion layer.

A dummy layer is formed on the hard mask layer. The dummy layer may be formed of a photosensitive layer, or undoped polysilicon layer with a high etch selectivity with respect to the hard mask layer 62b. A photolithography process is performed to form a first dummy pattern 64a and a second dummy pattern 64b on the hard mask layer 62b. A distance X between the first and second dummy patterns 64a and 64b may be larger than the minimum linewidth F and smaller than 2F (F≦X≦2F).

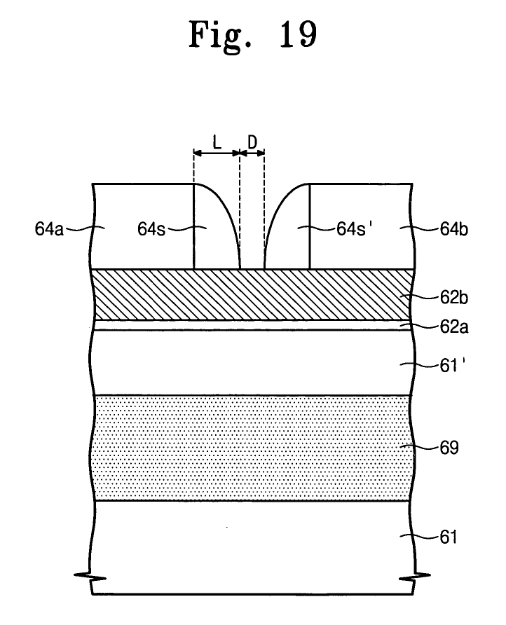

Referring to FIG. 19, spacers 64s and 64s′ are formed on sidewalls of the first and second dummy patterns 64a and 64b. The spacers 64s and 64s′ may be formed by depositing a material with an etch selectivity with respect to the dummy patterns and then performing an etch-back process on the resulting structure. The spacers 64s and 64s′ may be formed of a material with an etch selectivity with respect to the hard mask layer 62b. For example, when the hard mask layer 62b is formed of a silicon oxide layer, the spacers 64s and 64s′ may be formed of a silicon nitride layer. On the other hand, when the hard mask layer 62b may be formed of a silicon nitride layer, the spacers 64s and 64s′ are formed of a silicon oxide layer.

The width L of each of the spacers 64s and 64s′ is smaller than half of the distance X (L<(X/2)). Accordingly, a distance D between the spacer 54s of the dummy pattern 64a and the spacer 64s′ of the dummy pattern 64b is smaller than the minimum linewidth F (D<F). The distance between a pair of the spacers 64s and 64s′ determines the minimum distance between active regions adjacent to each other, which will be described in detail later. Accordingly, the memory cell can be formed such that it has the gap and width smaller than the allowable minimum linewidth F of a photolithography process.

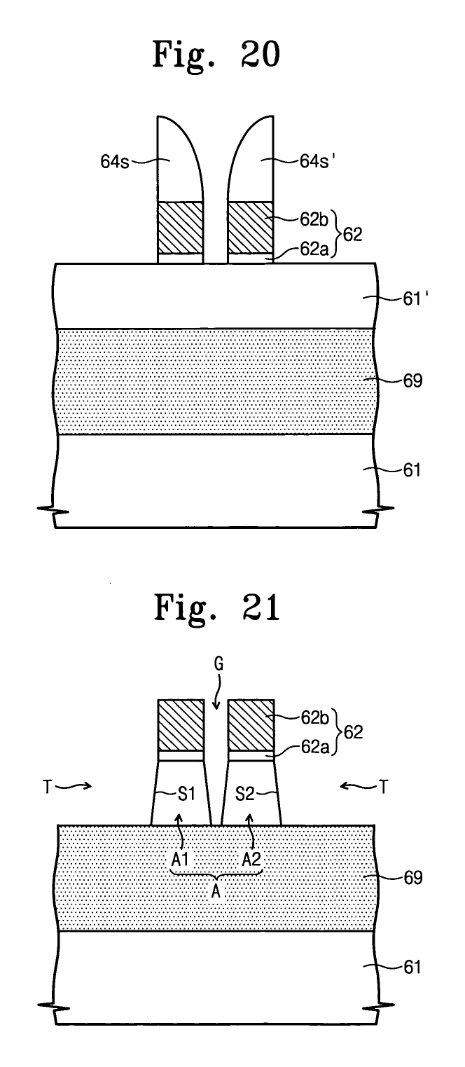

Referring to FIG. 20, the first and second dummy patterns 64a and 64b are removed to expose the hard mask layer 62b. Thereafter, the hard mask layer 62b and the buffer oxide layer 62a are etched using the spacers 64s and 64s′ as an etch mask, thereby forming hard mask patterns 62 (e.g., insulating layer patterns) having substantially the same width L as the spacer. As the hard mask patterns 62 are formed under the spacers 64s and 64s′, they have the same width (L) and distance (D) as those of the spacers 64s and 64s′.

Referring to FIG. 21, the spacers 64s and 64s′ are removed to expose the hard mask patterns 62 that face each other and has a narrow width L. Thereafter, a semiconductor substrate 61′ is etched using the mask patterns 62 as an etch mask. Alternatively, the etching of the semiconductor substrate 61′ may be performed without removing the spacers 64s and 64s′.

A narrow groove G is formed on the semiconductor substrate between the hard mask patterns 62, while wide trenches T are formed on the semiconductor substrate at both sides of the hard mask patterns 62 to expose the buried insulating layer 69. The width of the groove G is determined by the distance D between the spacers 64s and 64s′. An active region A is formed between the trenches T in such a way that it is separated into a first active region A1 and a second active region A2 by the groove G. The outer sides of the first and second active regions A1 and A2 correspond to a first side S1 and a second side S2, respectively.

Thereafter, the same processes as those in FIGS. 14A through 17A are performed to form a memory layer 63 and a gate conductive layer 65, and pattern them, thereby forming spacers 65W and impurity regions. Thereafter, the subsequent processes are performed to complete the nonvolatile memory device according to the second exemplary embodiment.

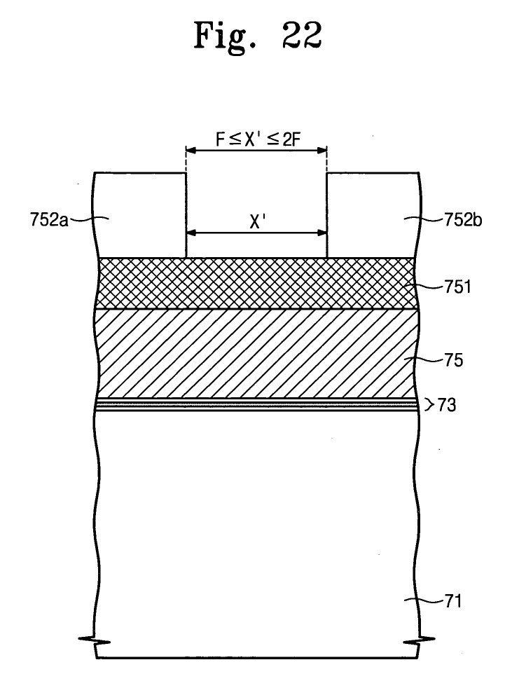

A method of fabricating the N-channel nonvolatile memory device according to the third exemplary embodiment of FIGS. 7A through 7E will now be described with reference to FIGS. 22 through 26.

FIGS. 22 through 26 are sectional views illustrating a method of fabricating a nonvolatile memory device according to a third exemplary embodiment of the present invention. FIGS. 22 through 26 are sectional views taken along a line III″-III″ of FIG. 7A.

Processes up to a process of forming a gate conductive layer 75 are identical to those in FIGS. 8A through 15C of the first exemplary embodiment.

Referring to FIG. 22, a hard mask layer 751 is formed on the gate conductive layer 75. For example, the hard mask layer 751 may be formed of a silicon nitride layer or a silicon oxide layer by a thin film deposition process. A dummy layer is formed on the hard mask layer 751, and a photolithography process is performed to form dummy patterns 752a and 752b. The dummy patterns 752a and 752b may be formed of photosensitive patterns or material patterns with a high etch selectivity with respect to the hard mask pattern 751, for example, of undoped polysilicon patterns.

A distance X′ between the dummy patterns 752a and 752b is larger than the minimum linewidth F and smaller than 2F (F≦X′≦2F). The distance X′ is determined by an inter-gate distance and the thickness of a gate to be formed.

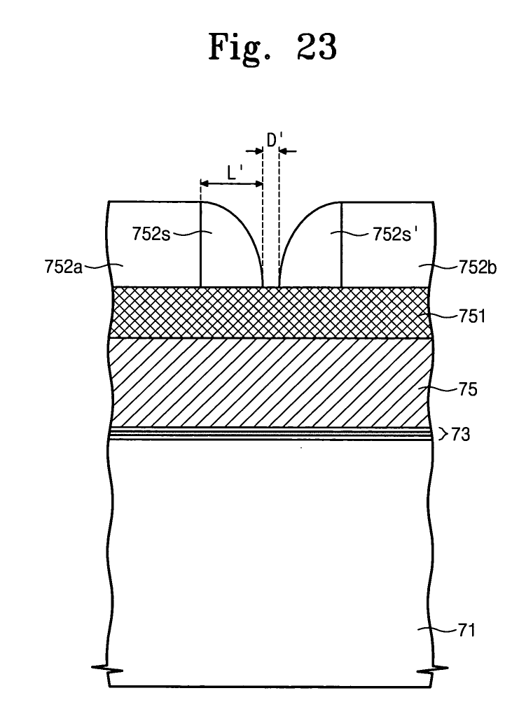

Referring to FIG. 23, insulative spacers 752s and 752s′ are formed on sidewalls of the dummy patterns 752a and 752b. The insulative spacers 752s and 752s′ may be formed by depositing an insulative material and then performing an etch-back process on the resulting structure. The insulative spacers 752s and 752s′ may be formed of a material with an etch selectivity with respect to the hard mask layer 751. For example, when the hard mask layer 751 is formed of a silicon oxide layer, the spacers 752s and 752s′ may be formed of a silicon nitride layer. On the other hand, when the hard mask layer 751 is formed of a silicon nitride layer, the spacers 752s and 752s′ may be formed of a silicon oxide layer. The width L′ of each of the spacers 752s and 752s′ is smaller than half of the distance X′ (L′<(X′/2)). Accordingly, a distance D′ between the spacer 752s of the dummy pattern 752a and the spacer 752s′ of the dummy pattern 752b is smaller than the minimum linewidth F (D′<F). The distance between a pair of the spacers 752s and 752s′ determines the minimum distance between memory cells adjacent to each other, which will be described in detail later. Accordingly, a pair of memory cells can be formed such that they have a gap therebetween and a width smaller than the allowable minimum linewidth F of a photolithography process.

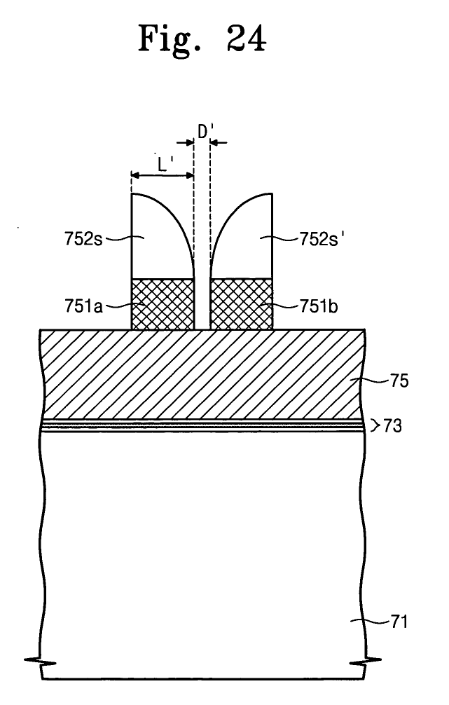

Referring to FIG. 24, the dummy patterns 752a and 752b are removed to expose the hard mask layer 751. Thereafter, the hard mask layer 751 is etched using the spacers 752s and 752s′ as an etch mask, thereby forming hard mask patterns 751a and 752b having substantially the same width L′ as the spacer.

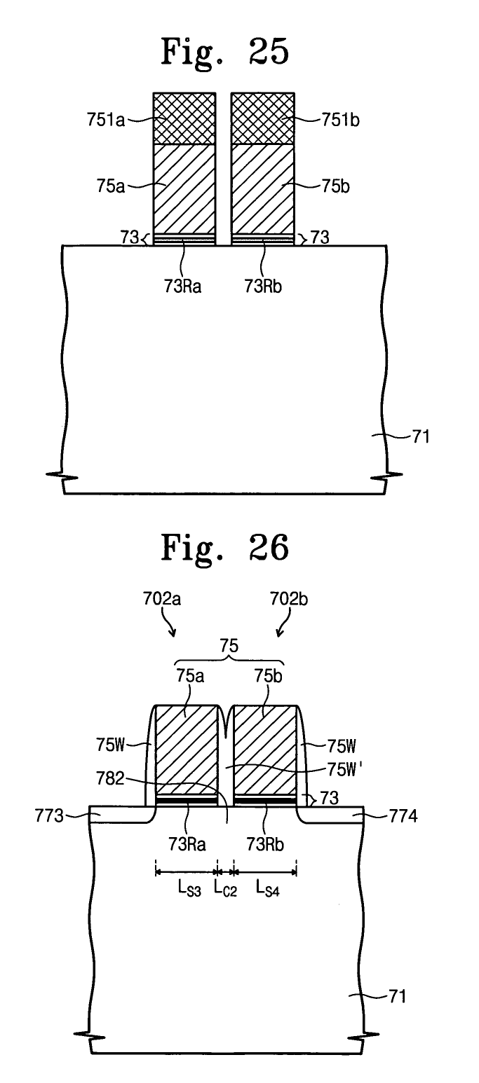

Referring to FIG. 25, the spacers 752s and 752s′ are removed, and the gate conductive layer 75 and a memory layer 73 are etched using the hard mask patterns 751a and 751b as an etch mask, thereby forming a pair of gate electrodes 75a and 75b and charge storage regions 73La, 73Lb, 75Ra an 73Rb.

Referring to FIG. 26, an insulating material is deposited and etch-backed. As a result, spacers 75W are formed on both sidewalls of the gate electrodes 75a and 75b, and an barrier insulating layer 75W′ is formed between the gate electrodes 75a and 75b.

High-concentration impurity ions are implanted to form impurity regions in active regions at both sides of the gate electrodes 75a and 75b. The impurity regions are formed by implanting arsenic or phosphor ions at an energy of about 30 to about 50 keV at a dose of about 1×10¹⁵ to 5×10¹⁵ atoms/cm². Similarly, for a P-channel memory cell, the impurity regions are formed by implanting arsenic or phosphor ions at an energy of about 30 to about 50 keV at a dose of about 1×10¹⁵ to 5×10¹⁵ atoms/cm². As a result of the above ion implantation process, a first impurity region 771, a second impurity region 772, and a first channel region 781 therebetween are formed at the first side S1, and a third impurity region 773, a fourth impurity region 774, and a second channel region 782 therebetween are formed at the second side S2.

A first sub-memory cell 701a and a second sub-memory cell 701b are formed in the first active region A1, while a third sub-memory cell 702a and a fourth sub-memory cell 702b are formed in the second active region A2. The first through fourth sub-memory cells constitute a unit memory device.

As described above, in exemplary embodiments of the present invention, the nonvolatile memory device is constructed such that two charge storage layers are physically isolated from each other. Therefore, exemplary embodiments of the present invention may solve the above-described difficulties of the conventional art caused by charge diffusion in high integration of memory devices. Moreover, the exemplary embodiments of the present invention may enhance the sensing margin characteristics of a multi-bit memory device. In addition, with the exemplary embodiments of the present invention, the conventional select gate necessary for enhancing the sensing margin is removed to make it possible to simplify control of the device and to reduce the device size.

Also, the nonvolatile memory devices according to exemplary embodiments of the present invention use the side portion of the trench as the channel region. Accordingly, the above-mentioned difficulty of the conventional art created at the edge of the trench can be effectively prevented and thus the characteristics and distribution of the memory device may be improved.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A nonvolatile memory device comprising:
a device isolation layer defining an active region protruding from a semiconductor substrate;
an active region separation layer isolating the active region into first and second active regions spaced apart from each other, the active region separation layer being narrower than the device isolation layer; and
first and second memory cells in the first and second active regions, respectively.

2. The nonvolatile memory device of claim 1, wherein the active region separation layer is shallower than the device isolation layer.

3. The nonvolatile memory device of claim 1, wherein the active region separation layer has a width that is smaller than a minimum linewidth.

4. The nonvolatile memory device of claim 1, wherein the first and second active regions have a width that is smaller than a minimum linewidth.

5. The nonvolatile memory device of claim 1, wherein the active region isolation layer is formed of an insulating material which is the same as that of the device isolation layer.

6. The nonvolatile memory device of claim 1, wherein the first and second memory cells are formed respectively at a first side of the first active region and a second side of the second active region, and the first and second sides are outer sides of the active region.

7. The nonvolatile memory device of claim 6, further comprising:
a gate line crossing the first and second active regions; and
a memory layer interposed between a gate line and the first and second active regions,
wherein the first and second memory cells comprise the memory layer on the first and second sides, respectively, and share the gate line with each other.

8. The nonvolatile memory device of claim 7, further comprising insulating patterns on upper portions of the first and second active regions.

9. The nonvolatile memory device of claim 7, wherein the memory layer comprises a tunnel oxide layer, a charge storage layer, and a blocking insulating layer.

10. The nonvolatile memory device of claim 9, wherein the charge storage layer comprises one selected from the group of a silicon nitride layer, a hafnium oxide layer, a lanthanum oxide layer, an aluminum oxide layer, a nanocrystal layer, or a combination thereof.

11. The nonvolatile memory device of claim 7, wherein the first memory cell further comprises first and second impurity regions that are spaced apart from each other on the first side to define a first channel region therebetween, and the second memory cell further comprises third and fourth impurity regions that are spaced apart from each other on the second side to define a second channel region therebetween.

12. The nonvolatile memory device of claim 11, wherein the gate line comprises a pair of gate electrodes spaced apart from each other, the first memory cell comprises a first pair of sub-memory cells that share the first and second impurity regions and are controlled respectively by the pair of gate electrodes, and the second memory cell comprises a second pair of sub-memory cells that share the third and fourth impurity regions and are controlled respectively by the pair of gate electrodes.

13. A method of fabricating a nonvolatile memory device, the method comprising:
forming a trench for a device isolation layer defining an active region on a semiconductor substrate and a groove separating the active region into a first active region and a second active region, the groove being narrower than the trench; and
forming a first memory cell and a second memory cell in the first active region and the second active region, respectively.

14. The method of claim 13, wherein the groove is shallower than the trench.

15. The method of claim 13, wherein forming the trench and the groove comprises:
forming a pair of mask patterns in a predetermined region on the semiconductor substrate, the pair of mask patterns being spaced apart from each other by a predetermined distance smaller than a minimum linewidth; and
etching the semiconductor substrate using the pair of mask patterns.

16. The method of claim 15, wherein forming the pair of mask patterns comprises:
stacking an insulating layer on the semiconductor substrate;
forming a dummy layer on the insulating layer and performing a photolithography process on the dummy layer to form a first dummy pattern and a second dummy pattern;
forming a pair of spacers facing each other on sidewalls of the first and second dummy patterns;
removing the first and second dummy patterns; and
etching the insulating layer using the pair of spacers as an etch mask to form the mask patterns.

17. The method of claim 16, wherein the first and second dummy patterns have a minimum linewidth (F), a distance (X) between the dummy patterns neighboring each other is larger than F and smaller than 2F (F≦X≦2F), the pair of mask patterns have a width L smaller than half of X (L<(X/2)), and a minimum distance (D) between the mask patterns neighboring each other is smaller than F.

18. The method of claim 16, wherein the insulating layer is a stack of a silicon oxide layer and a silicon nitride layer.

19. The method of claim 15, further comprising forming a device isolation layer and an active region separating layer that fill the trench and the groove, respectively,
wherein the device isolation layer exposes first and second sides that are adjacent respectively to outer sides of upper portions of the first and second active regions, and the first and second memory cells are formed on the first and second sides, respectively.

20. The method of claim 19, wherein the forming of the first and second memory cells comprises:
forming a memory layer on the entire upper surface of the semiconductor substrate; and
forming a gate line crossing the first and second active regions on the memory layer.

21. The method of claim 20, wherein the memory layer is formed by sequentially depositing a tunnel oxide layer, a charge storage layer, and a blocking insulating layer.

22. The method of claim 20, wherein forming the first and second memory cells comprises:
forming impurity regions at both sides of the gate line using an ion implantation process, to form first and second impurity regions on the first side, a first channel region between the first and second impurity regions, third and fourth impurity regions on the second side, and a second channel region between the third and fourth impurity regions.

23. The method of claim 22, wherein the gate line is formed of a pair of gate electrodes spaced apart from each other.
